(19) United States
(12) Patent Application Publication
(10) Pub. No.: US 2010/0059895 A1
(43) Pub. Date: Mar. 11, 2010

(54) SEMICONDUCTOR DEVICE HAVING AN INTERLAYER INSULATING FILM WIRING LAMINATED STRUCTURE SECTION AND METHOD OF FABRICATING THE SAME

(75) Inventor: Shinji WAKISAKA, Tokyo (JP)

Correspondence Address: FRISHAUF, HOLTZ, GOODMAN & CHICK, PC, 220 Fifth Avenue, 16TH Floor, NEW YORK, NY, 10001-7708, US

(73) Assignee: Casio Computer Co., Ltd., Tokyo (JP)

(21) Appl. No.: 12/555,997

(22) Filed: Sep. 9, 2009

(30) Foreign Application Priority Data
Sep. 9, 2008 (JP) 2008-230870

(51) Int. Cl. H01L 23/522; H01L 21/768

(52) U.S. Cl. 257/774; 438/637; 257/E23.145; 257/E21.575

(57) ABSTRACT

In the manufacture of a semiconductor, in unnecessary semiconductor device formation areas 22b and 22c, a columnar electrode 14 made of copper is formed only in an area excluding an area corresponding to a dicing street 23 and both sides of the dicing street 23, and is not formed in the area corresponding to the dicing street 23 and both sides of the dicing street 23. As a result, the dicing blade is prevented from being clogged with copper. In this case, a plurality of layers of low-dielectric film and the same number of layers of wiring are formed on a semiconductor wafer such that they are alternately laminated, and the columnar electrode is formed on a connection pad portion of upper layer wiring formed on the low-dielectric film wiring laminated structure section with an insulating film therebetween.

### CROSS-REFERENCE TO RELATED APPLICATION

This application is based upon and claims the benefit of priority from the prior Japanese Patent Application No. 2008-230870, filed Sep. 9, 2008, the entire contents of which is incorporated herein by reference.

### BACKGROUND OF THE INVENTION

1. Field of the Invention

The present invention relates to a semiconductor device having an interlayer insulating film wiring laminated structure section and method of fabricating the same.

2. Description of the Related Art

As a semiconductor device mounted in compact electronic devices such as portable electronic devices, a chip size package (CSP) having a shape and an area that are substantially equal to those of a semiconductor substrate is known. Among CSPs, a CSP in which packaging is completed in a wafer state and separated into individual semiconductor devices by dicing is also referred to as a wafer level package (WLP).

In a semiconductor device disclosed in Japanese Patent Application Laid-Open (Kokai) Publication No. 2004-349461, wiring is formed on the upper surface of an insulating film on a semiconductor substrate, a columnar electrode is provided on the upper surface of a connection pad portion of the wiring, a sealing film is formed on the upper surface of the insulating film including the wiring such that the upper surface of the sealing film is flush with the upper surface of the columnar electrode, and a solder ball is provided on the upper surface of the columnar electrode.

The above-mentioned Japanese Patent Application Laid-Open (Kokai) Publication No. 2004-349461 also discloses a semiconductor device in which an interlayer insulating film wiring laminated structure section having a laminated structure including interlayer insulating films and wiring are provided between the semiconductor substrate and the insulating film. In a semiconductor device such as this, when the distance between the wiring in the interlayer insulating film wiring laminated structure section decreases due to miniaturization, the capacity between the wiring increase, causing the delay of signals transmitted over the wiring to be increased.

To solve this problem, low-dielectric materials referred to as, for example, low-k materials are receiving attention as a material used for the interlayer insulating film. The low-k materials have a dielectric constant lower than a dielectric constant of 4.2 to 4.0 of silicon oxide generally used as the material for the interlayer insulating film, and examples of the low-k materials include SiOC obtained by doping silicon oxide (SiO2) with carbon (C), SiOCH further containing H, etc. To further reduce the dielectric constant, a porous low-dielectric film containing air is also being studied.

In a manufacturing method of a semiconductor device that has a low-dielectric film wiring laminated structure section having a laminated structure including low-dielectric films serving as the interlayer insulating film and wiring, the low-dielectric films and wiring are laminated and formed on a semiconductor substrate that is in a wafer state (referred to, hereinafter, as semiconductor wafer), and then an insulating film, upper layer wiring, columnar electrodes, a sealing film and solder balls are formed thereon. Subsequently, the semiconductor wafer is separated into individual semiconductor devices by dicing.

However, when the low-dielectric film is cut by a dicing blade, numerous chips and damage occur on the cut surface of the low-dielectric film because of its fragility.

Therefore, the removal of a portion, which corresponds to a dicing street, of a low-dielectric film formed on a semiconductor wafer along with a passivation film formed thereon made of an inorganic material such as silicon nitride by a laser beam irradiation at a relatively early stage is being examined. Because the laser beam instantly melts the low-dielectric film to be irradiated by instantaneously superheating to a high temperature, an effect of preventing chipping of and damage to the low-dielectric film is achieved.

However, in a manufacturing method of a semiconductor device in which a portion of a low-dielectric film on a semiconductor wafer, which corresponds to a dicing street, is removed along with a passivation film formed thereon by a laser beam irradiation at a relatively early stage, because the adhesion intensity between the low-dielectric film and the passivation film on the removal surface formed by a laser beam irradiation is low, there is a possibility that a portion of the removal surface chips off, and the chipped portion causes a problem in later processes.

On the other hand, in the manufacture of a semiconductor device such as described above, when semiconductor devices to be manufactured are for development and testing purposes or for small-quantity production, in some cases, various types of integrated circuits having different circuit configurations, sizes, functions, and the like are formed on a single semiconductor wafer, and only necessary integrated circuits are formed into semiconductor devices and removed. In such a case, the semiconductor wafer includes a plurality of semiconductor device formation areas of different sizes, and the plurality of semiconductor device formation areas include necessary semiconductor device formation areas and unnecessary semiconductor device formation areas.

That is, the necessary semiconductor device formation areas are areas where currently necessary integrated circuits, which will be removed from the semiconductor wafer, have been formed, and the unnecessary semiconductor device formation areas are areas where currently unnecessary integrated circuits, which need not be formed into semiconductor devices and will not be removed, have been formed. When the semiconductor wafer is cut along dicing streets formed along the periphery of the necessary semiconductor device formation areas, semiconductor devices having the necessary semiconductor device formation areas are obtained.

For example, in the case shown in FIG. 3 of the present application, dicing streets 23 formed along the upper sides and the lower sides of necessary semiconductor device formation areas 22a overlap with first unnecessary semiconductor device formation areas 22b and second unnecessary semiconductor device formation areas 22c. As a result, when the dicing streets 23 formed along the upper sides and the lower sides of the necessary semiconductor device formation areas 22a are cut for removing the necessary semiconductor device formation areas 22a as semiconductor devices, the first unnecessary semiconductor device formation areas 22b and the second unnecessary semiconductor device formation areas 22c are partially cut. In this case, no problem occurs even when the first unnecessary semiconductor device formation areas 22b and the second unnecessary semiconductor device formation areas 22c are partially cut.

However, in a case where a plurality of columnar electrodes made of electrolytic copper plating are formed on the first unnecessary semiconductor device formation areas 22b and the second unnecessary semiconductor device formation areas 22c, when, among the plurality of columnar electrodes, columnar electrodes formed on the dicing streets 23 formed along the upper sides and the lower sides of the necessary semiconductor device formation areas 22a are cut by a dicing blade, the dicing blade is clogged with copper, causing the life of the dicing blade to be decreased.

As described above, there is a problem in the manufacturing method of a semiconductor device in which a portion of a low-dielectric film on a semiconductor wafer, which corresponds to a dicing street, is removed along with a passivation film formed thereon by a laser beam irradiation at a relatively early stage. In this method, the adhesion intensity between the low-dielectric film and the passivation film on the removal surface formed by a laser beam irradiation is low, and in the case where a portion of the removal surface chips off, this chipped portion will cause a problem in later processes.

Additionally, there also is a problem in the manufacturing method of a semiconductor device in which a semiconductor device having a necessary semiconductor device formation area is obtained from a semiconductor wafer including necessary semiconductor device formation areas and unnecessary semiconductor device formation areas. In this method, in a case where a plurality of columnar electrodes made of electrolytic copper plating are formed on the first unnecessary semiconductor device formation areas 22b and the second unnecessary semiconductor device formation areas 22c, when, among the plurality of columnar electrodes, columnar electrodes formed on the dicing streets 23 formed along the upper sides and the lower sides of the necessary semiconductor device formation areas 22a are cut by a dicing blade, the dicing blade is clogged with copper, causing the life of the dicing blade to be decreased.

### BRIEF SUMMARY OF THE INVENTION

The present invention has been conceived in light of the above-described problems, and the object of the present invention is to provide a manufacturing method of a semiconductor device in which any portion of a removal surface of a low-dielectric film removed by a laser beam irradiation is prevented from chipping off, and the decrease of the life of a dicing blade cause by being clogged with copper is suppressed.

Additionally, in the unnecessary semiconductor device formation area, a plurality of columnar electrodes made of copper are formed only in areas excluding areas corresponding to dicing streets and both sides of the dicing streets. That is, the columnar electrodes are not formed in the areas corresponding to the dicing streets and both sides of the dicing streets. As a result, the dicing blade is prevented from being clogged with copper. In this case, a plurality of layers of low-dielectric film and the same number of layers of wiring are formed on a semiconductor wafer such that they are alternately laminated, and a columnar electrode is formed on a connection pad portion of upper layer wiring formed on the low-dielectric film wiring laminated structure section with an insulating film therebetween.

In order to achieve the above-described purpose, in accordance with one aspect of the present invention, there is provided a manufacturing method of a semiconductor device, comprising the steps of: preparing a semiconductor wafer, which has a plurality of semiconductor device formation areas, and on which a low-dielectric film wiring laminated structure section where a low-dielectric film and wiring are laminated is formed; irradiating a laser beam to form a groove by removing an area of the low-dielectric film wiring laminated structure section corresponding to a dicing street of the necessary semiconductor device formation area by a laser beam irradiation; and forming a protective film on the low-dielectric film wiring laminated structure section and within the groove.

According to the present invention, an area of the low-dielectric film wiring laminated structure section corresponding to a dicing street of the necessary semiconductor device formation area is removed by a laser beam irradiation, and thereby forming a groove. Then, a protective film is formed within the groove and on the low-dielectric film wiring laminated structure section. Therefore, the removal surface of the low-dielectric film formed by a laser beam irradiation is covered by the protective film, thereby preventing any portion of the removal surface from chipping off. Moreover, in the necessary semiconductor device formation area, a columnar electrode is formed on a connection pad portion of upper layer wiring, and in an unnecessary semiconductor device formation area, a columnar electrode is formed on a connection pad portion of upper layer wiring in an area excluding a non-formation area that includes the area corresponding to the dicing street of the necessary semiconductor device formation area. Therefore, there is no possibility of a columnar electrode in an unnecessary semiconductor device formation area being cut by a dicing blade, and the dicing blade is prevented from being clogged with copper. Thus, the decrease of the life of a dicing blade caused by being clogged with copper is suppressed.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE DRAWINGS

The accompanying drawings, which are incorporated in and constitute a part of the specification, illustrate embodiments of the invention, and together with the general description given above and the detailed description of the embodiments given below, serve to explain the principles of the invention.

FIG. 1A is a top view of an example of a semiconductor device manufactured by a manufacturing method according to the first embodiment of the present invention;

FIG. 1B is a cross-sectional view taken along line B-B in FIG. 1A;

FIG. 2 is a top view explaining a planar state of a portion of a semiconductor wafer used for development and testing purposes or for small-quantity production;

FIG. 3 is a top view explaining dicing streets in relation to the semiconductor wafer shown in FIG. 2;

FIG. 4A and FIG. 4B are cross-sectional views of an initially prepared structure in manufacturing the semiconductor device shown in FIG. 1. FIG. 4A is a cross-sectional view of a portion of necessary semiconductor device formation area taken along line IVA-IVA in FIG. 3, and FIG. 4B is a cross-sectional view of a portion of unnecessary semiconductor device formation area taken along line IVB-IVB in FIG. 3;

FIG. 5A and FIG. 5B are cross-sectional views of the process subsequent to that in FIG. 4A and FIG. 4B;

FIG. 6A and FIG. 6B are cross-sectional views of the process subsequent to that in FIG. 5A and FIG. 5B;

FIG. 7A and FIG. 7B are cross-sectional views of the process subsequent to that in FIG. 6A and FIG. 6B;

FIG. 8A and FIG. 8B are cross-sectional views of the process subsequent to that in FIG. 7A and FIG. 7B;

FIG. 9A and FIG. 9B are cross-sectional views of the process subsequent to that in FIG. 8A and FIG. 8B;

FIG. 10A and FIG. 10B are cross-sectional views of the process subsequent to that in FIG. 9A and FIG. 9B;

FIG. 11 is a top view in the state shown in FIG. 10A and FIG. 10B;

FIG. 12A and FIG. 12B are cross-sectional views of the process subsequent to that in FIG. 10A and FIG. 10B;

FIG. 13A and FIG. 13B are cross-sectional views of the process subsequent to that in FIG. 12A and FIG. 12B;

FIG. 14A and FIG. 14B are cross-sectional views of the process subsequent to that in FIG. 13A and FIG. 13B;

FIG. 15A and FIG. 15B are cross-sectional views of the process subsequent to that in FIG. 14A and FIG. 14B;

FIG. 16A and FIG. 16B are cross-sectional views of the process subsequent to that in FIG. 15A and FIG. 15B;

FIG. 17 is a cross-sectional view of an example of a semiconductor device manufactured by a manufacturing method according to the second embodiment of the present invention;

FIG. 18A and FIG. 18B are cross-sectional views, which are given in a manner similar to that in FIG. 4A and FIG. 4B, of a predetermined process in manufacturing the semiconductor device shown in FIG. 17;

FIG. 19A and FIG. 19B are cross-sectional views of the process subsequent to that in FIG. 18A and FIG. 18B;

FIG. 20A and FIG. 20B are cross-sectional views of a the process subsequent to that in FIG. 19A and FIG. 19B;

FIG. 21A and FIG. 21B are cross-sectional views of the process subsequent to that in FIG. 20A and FIG. 20B;

FIG. 22 is a cross-sectional view of an example of a semiconductor device manufactured by a manufacturing method according to the third embodiment of the present invention;

FIG. 23 is a top view of a process similar to that in FIG. 11 in a manufacturing method according to the fourth embodiment of the present invention;

FIG. 24 is a top view of a process similar to that in FIG. 11 in a manufacturing method according to the fifth embodiment of the present invention;

FIG. 25 is a top view of an example of an exposure mask used in the manufacturing method according to the first embodiment;

FIG. 26 is a top view of an example of an exposure mask used in another manufacturing method;

FIG. 27 is a top view of an example of an exposure mask also used in another manufacturing method; and

FIG. 28 is a top view of another example of the exposure mask shown in FIG. 26.

### DETAILED DESCRIPTION OF THE PREFERRED EMBODIMENTS

The present invention will hereinafter be described in detail with reference to the preferred embodiments shown in the accompanying drawings.

### First Embodiment

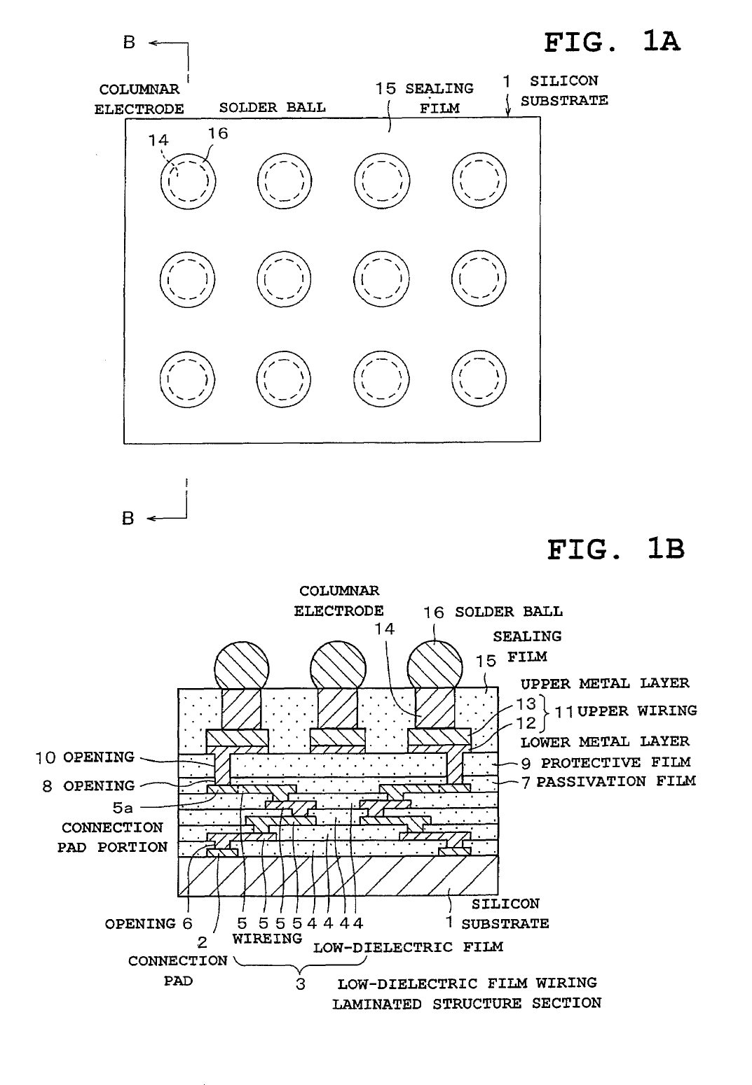

FIG. 1A is a top view of an example of a semiconductor device manufactured by a manufacturing method according to the first embodiment of the present invention, and FIG. 1B is a cross-sectional view taken along line B-B.

The semiconductor device includes a silicon substrate (semiconductor substrate) 1, and elements constituting an integrated circuit section, such as a transistor, a diode, a resistor, a capacitor (not shown), are formed on the upper surface of the silicon substrate 1. A connection pad 2 made of aluminum-based metal or the like is provided on the upper surfaces of the elements so as to connect to each of the elements. Although only two connection pads 2 are shown in FIG. 1, in actuality, numerous connection pads 2 are arrayed on the silicon substrate 1.

Also, a low-dielectric film wiring laminated structure section 3 constituting the integrated circuit section is formed on the upper surface of the silicon substrate 1. The low-dielectric film wiring laminated structure section 3 has a structure in which a plurality of layers, such as four layers of a low-dielectric film 4 and the same number of layers of wiring 5 made of, for example, a copper-type or an aluminum-type metal are alternately laminated. In this embodiment, the wiring 5 of respective layers are interconnected between layers. One end section of the wiring 5 of the bottommost layer is connected to the connection pad 2 via an opening 6 provided in the low-dielectric film 4 of the bottommost layer. A connection pad portion 5a of the wiring 5 of the uppermost layer is arranged on the upper surface periphery of the low-dielectric film 4 of the uppermost layer.

Examples of a material of the low-dielectric film 4 include a polysiloxane-based material having a Si—O bond and a Si—H bond (HSQ: hydrogen silsesquioxane having a relative dielectric constant of 3.0), a polysiloxane-based material having a Si—O bond and a Si—CH3 bond (MSQ: methyl silsesquioxane having a relative dielectric constant of 2.7 to 2.9), a carbon-doped silicon oxide (SiOC having a relative dielectric constant of 2.7 to 2.9), and an organic polymer-based low-k material. A material having a relative dielectric constant of 3.0 or lower and a glass transition temperature of 400° C. or higher is usable. Examples of the organic polymer-based low-k material include “SILK (having a relative dielectric constant of 2.6)” manufactured by Dow Chemical Company, “FLARE (having a relative dielectric constant of 2.8)” manufactured by Honeywell Electronic Materials. Here, the glass transition temperature of 400° C. or higher is a condition for withstanding a temperature during the manufacturing process described hereafter. Note that a porous type of each of the above materials may also be used.

Besides the above-mentioned materials, a material which has a dielectric constant exceeding 3.0 in a normal condition but has a dielectric constant of 3.0 or lower and a glass transition temperature of 400° C. or higher when porous may be used as the material for the low-dielectric film 4. For example, fluorinated silicate glass (FSG having a relative dielectric constant of 3.5 to 3.7), boron-doped silicate glass (BSG having a relative dielectric constant of 3.5), or silicon oxide (having a relative dielectric constant of 4.0 to 4.2) may be used.

A passivation film 7 made of an inorganic material, such as silicon nitride, is provided on the upper surface of the low-dielectric film 4 of the uppermost layer including the wiring 5 of the uppermost layer. An opening 8 is provided in a portion of the passivation film 7 corresponding to the connection pad portion 5a of the wiring 5 of the uppermost layer. A protective film 9 made of an organic resin, such as polyimide resin, is provided on the top surface of the passivation film 7. An opening 10 is formed in a portion of the protective film 9 corresponding to the opening 8 in the passivation film 7.

Upper-layer wiring 11 is provided on the top surface of the protective film 9, and has a two-layer structure including a base metallic layer 12 and an upper metallic layer 13. The base metallic layer 12 made of copper and the like is provided on the top surface of the protective film 9, and the upper metallic layer 13 made of copper is provided on the top surface of the base metallic layer 12. One end portion of the upper-layer wiring 11 is connected to the connection pad portion 5a of the wiring 5 of the uppermost layer via the opening 8 formed in the passivation film 7 and the opening 10 formed in the protective film 9.

A columnar electrode 14 made of copper is provided on the upper surface of the connection pad portion of the upper-layer wiring 11. On the upper surface of the protective film 9 including the upper-layer wiring 11, a sealing film 15 made of an organic material such as an epoxy-based resin is formed such that the upper surface of the sealing film 15 is flush with the upper surface of the columnar electrode 14. A solder ball 16 is provided on the upper surface of the columnar electrode 14. In this embodiment, a plurality of solder balls 16 or, in other words, a plurality of columnar electrodes 14 are arranged in a matrix form.

Next, an example of a manufacturing method of this semiconductor device will be described.

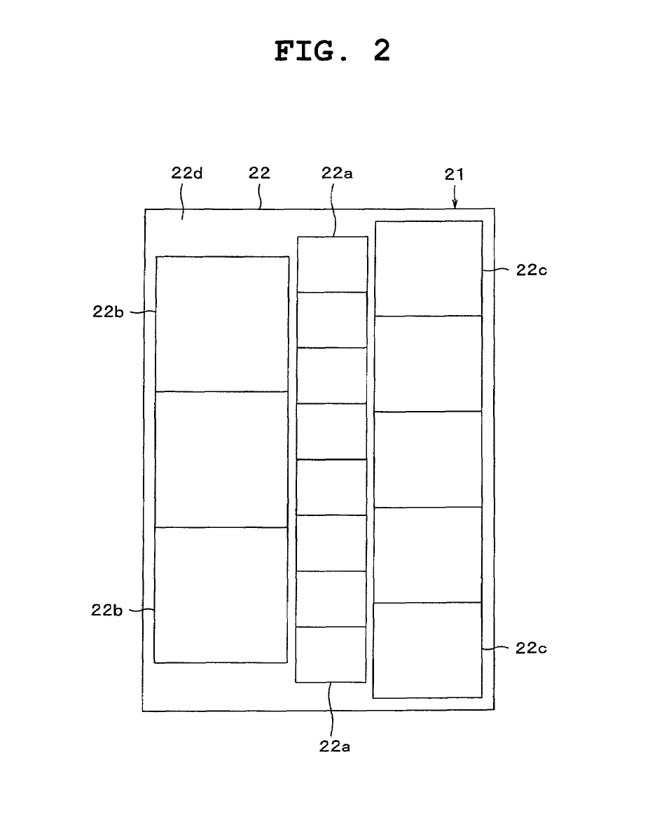

As shown in FIG. 2, an necessary semiconductor device formation area 22a, a first unnecessary semiconductor device formation area 22b, a second unnecessary semiconductor device formation area 22c, and an surplus area 22d having different planar shapes (square or rectangular) and sizes are provided within a rectangular area 22 that is a portion of a silicon substrate in a wafer-state (hereinafter referred to as a semiconductor wafer 21).

In this embodiment, eight necessary semiconductor device formation areas 22a having the same shape and size are arranged consecutively in the longitudinal direction at the center in the lateral direction of the area 22. In addition, three first unnecessary semiconductor device formation areas 22b having the same size and shape are arranged consecutively in the longitudinal direction on the left side of the area 22. Moreover, five second unnecessary semiconductor device formation areas 22c having the same size and shape are arranged consecutively in the longitudinal direction on the right side of the area 22.

On the upper surface of the semiconductor wafer 21, various types of integrated circuits (not shown) are formed in the necessary semiconductor device formation area 22a, the first unnecessary semiconductor device formation area 22bs, and second unnecessary semiconductor device formation area 22c. To manufacture semiconductor devices for development and testing purposes, or for small-quantity production, various types of integrated circuits having different circuit configurations, sizes, functions, etc. are formed on a single semiconductor wafer 21, and only necessary integrated circuits are formed into semiconductor devices and removed.

Here, the eight necessary semiconductor device formation areas indicated by reference numeral 22a are areas where currently necessary integrated circuits, which will be removed from the semiconductor wafer 21, have been formed. The first and second unnecessary semiconductor device formation areas indicated by reference numerals 22b and 22c are areas where currently unnecessary integrated circuits, which need not be formed into semiconductor devices and will not be removed, have been formed.

In the first embodiment, reference numeral 22a indicates the necessary semiconductor device formation area, and reference numerals 22b and 22c indicate the unnecessary semiconductor device formation areas. However, each area 22a to 22c are capable of being necessary semiconductor device formation area and unnecessary semiconductor device formation area. It is simply that any semiconductor device formation area required to be removed from the semiconductor wafer 21 is called necessary semiconductor device formation area. In each of the semiconductor device formation area, namely, the necessary semiconductor device formation area 22a, the unnecessary semiconductor device formation area 22b, and the unnecessary semiconductor device formation area 22c, an integrated circuit for providing a predetermined function having the low-dielectric film wiring laminated structure section 3 has been formed.

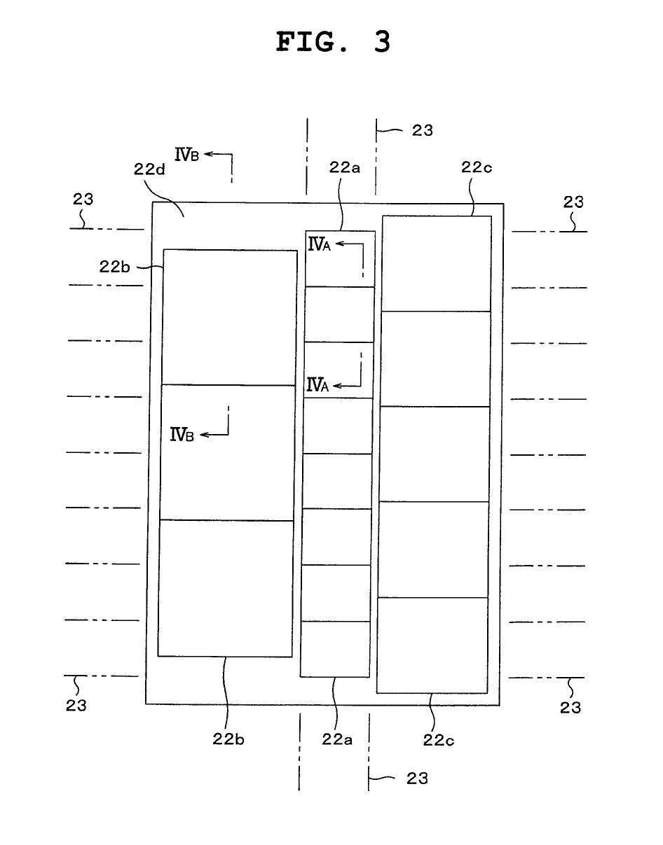

Under conditions such as above, in the end, the eight necessary semiconductor device formation areas indicated by reference numeral 22a are separated into individual pieces. In addition, the remaining first and second unnecessary semiconductor device formation areas indicated by reference numerals 22b and 22c, and the surplus area 22d are discarded as unnecessary sections. Therefore, no problems occur even when linear dicing streets 23 are formed, as indicated by the two-dot chain lines in FIG. 3, in areas along each of the four sides of the eight necessary semiconductor device formation areas 22a, and set over areas where integrated circuits in the first unnecessary semiconductor device formation areas 22b and the second unnecessary semiconductor device formation areas 22c are formed. As just described, in FIG. 3, the dicing streets 23 formed along the upper sides and the lower sides of the necessary semiconductor device formation areas 22a pass through each area of the first unnecessary semiconductor device formation areas 22b and the second unnecessary semiconductor device formation areas 22c.

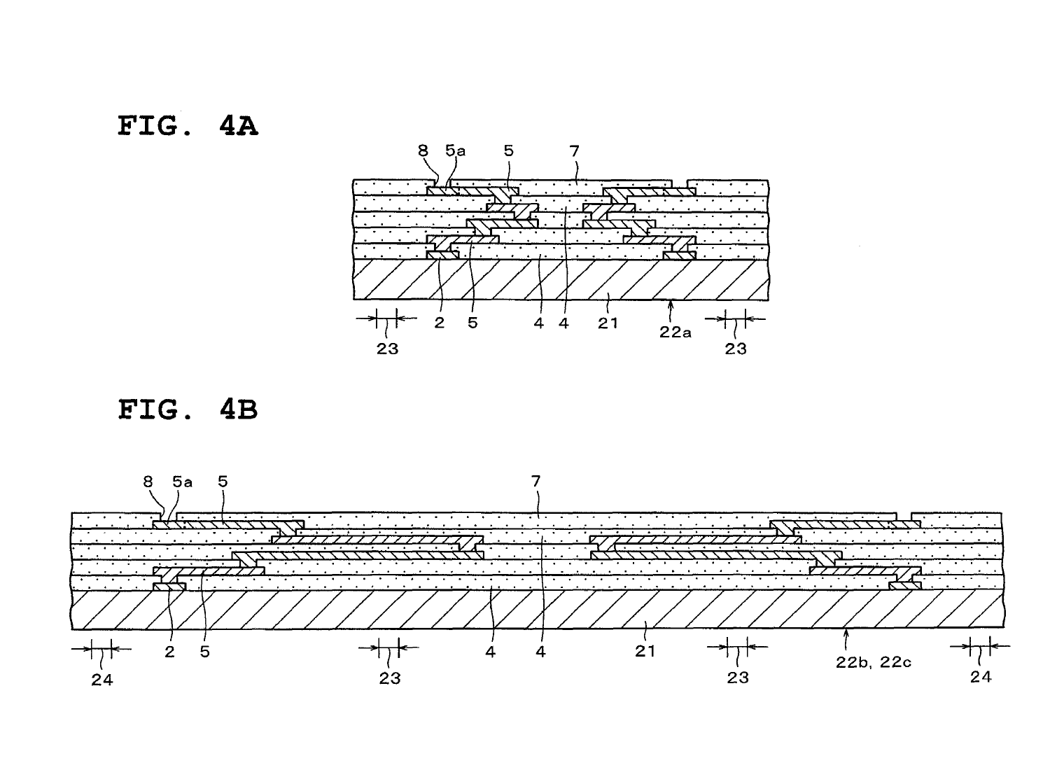

To manufacture the semiconductor device shown in FIG. 1A and FIG. 1B from the necessary semiconductor device formation area 22a of the semiconductor wafer 21, first, a structure shown in FIG. 4A and FIG. 4B is prepared. Here, FIG. 4A is a cross-sectional view of a necessary semiconductor device formation area 22a section along line IVA-IVA in FIG. 3, and FIG. 4B is a cross-sectional view of a first unnecessary semiconductor device formation area 22b section and a second unnecessary semiconductor device formation area 22c section along line IVB-IVB in FIG. 3.

In the prepared structure, in any of the necessary semiconductor device formation area 22a section, the first unnecessary semiconductor device formation area 22b section, and the second unnecessary semiconductor device formation area 22c section, the connection pad 2, the low-dielectric film 4 and the wiring 5 having four layers respectively, and the passivation film 7 are formed on the semiconductor wafer 21. The center of the connection pad portion 5a of the wiring 5 of the uppermost layer is exposed via the opening 8 formed in the passivation film 7. To facilitate understanding, the first unnecessary semiconductor device formation area 22b and the second unnecessary semiconductor device formation area 22c are described as having the same structure.

Here, in FIG. 4A, areas indicated by reference numeral 23 are areas corresponding to dicing streets formed along the left side and the right side of the necessary semiconductor device formation area 22a at a portion along line IVA-IVA in FIG. 3. In FIG. 4B, areas indicated by reference numeral 24 are areas corresponding to virtual dicing streets formed along the upper side and the lower side of the necessary semiconductor device formation area 22a at a portion along line IVB-IVB in FIG. 3. In other words, in the unnecessary semiconductor device formation areas 22b and 22c, the areas indicated by the reference numeral 23 are areas corresponding to the intermediate areas of the integrated circuit sections and are not areas corresponding to the end sections of the integrated circuit sections or, in other words, are not areas on which dicing should be performed.

In this instance, as shown in FIG. 4B, the unnecessary semiconductor device formation area 22b and 22c sections overlaps with the dicing streets 23 formed along the upper side and the lower side of the necessary semiconductor device formation area 22a on the right-hand side of the unnecessary semiconductor device formation areas 22b and 22c at the portion along the line IVB-IVB in FIG. 3.

As shown in FIG. 4A, in the necessary semiconductor device formation area 22a section, the connection pad 2 and the wiring 5 are arranged on the inner sides of (between) the dicing streets 23. That is, although the low-dielectric film 4 is formed in areas corresponding to the dicing streets 23 around the periphery of the necessary semiconductor device formation area 22a, the wiring 5 is not formed. On the other hand, as shown in FIG. 4B, in the unnecessary semiconductor device formation area 22b and 22c sections, the low-dielectric film 4 and the wiring 5 are formed in some of the areas overlapping with the dicing streets 23.

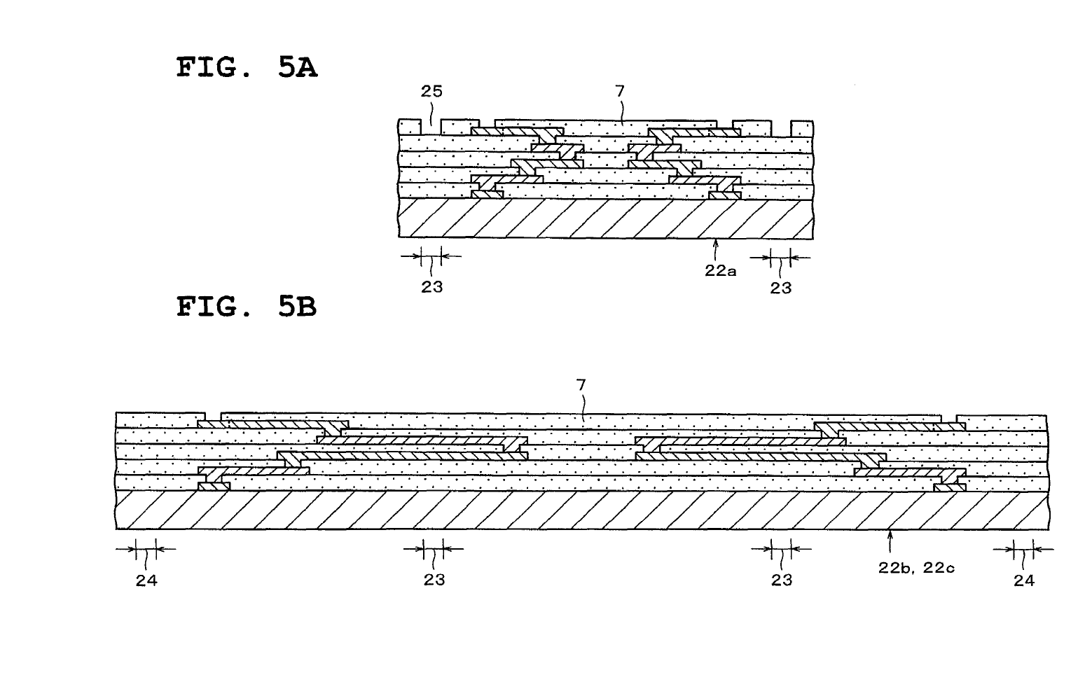

After the structure shown in FIG. 4A and FIG. 4B is prepared, as shown in FIG. 5A, a first groove 25 is formed by photolithography on the passivation film 7 in the areas corresponding to the dicing streets 23 around the periphery of the necessary semiconductor device formation area 22a. In this embodiment, as shown in FIG. 5B, in the unnecessary semiconductor device formation areas 22b and 22c, a groove such as this is not formed in the passivation film 7.

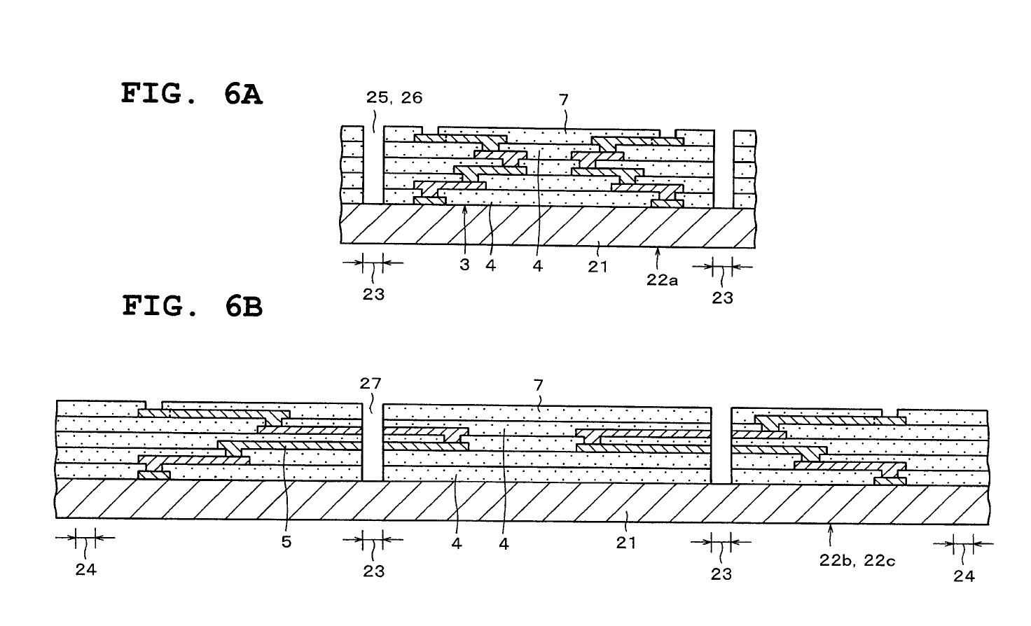

Next, as shown in FIG. 6A, a second groove 26 is formed by laser processing through a laser beam irradiation in the four layers of the low-dielectric film 4 in an area corresponding to the first groove 25 (namely the dicing street 23) in the passivation film 7 in the necessary semiconductor device formation area 22a section. In this state, the upper surface of the semiconductor wafer 21 on the dicing street 23 is exposed via the first groove 25 and the second groove 26. Additionally, as a result of the four layers of the low-dielectric film 4 and the passivation film 7 laminated on the semiconductor wafer 21 being separated by the first groove 25 and the second groove 26, the low-dielectric film wiring laminated structure section 3 shown in FIG. 1 is formed.

Also, as shown in FIG. 6B, in the unnecessary semiconductor device formation area 22b and 22c sections, a third groove 27 is formed by laser processing through a laser beam irradiation in the passivation film 7 and the four layers of low-dielectric film 4 on the dicing street 23. In this instance, in the unnecessary semiconductor device formation areas 22b and 22c, a portion of the wiring 5 overlaps with the dicing street 23. Therefore, the wiring 5 in the overlapping portion is removed. In this state, the upper surface of the semiconductor wafer 21 on the dicing street 23 is exposed via the third groove 27.

In the unnecessary semiconductor device formation area 22b and 22c sections, the third groove 27 has been formed by the passivation film 7, the low-dielectric film 4, and the wiring 5 in a portion on the dicing street 23 being removed by a laser beam irradiation. Therefore, these removal surfaces are exposed. In this instance, the adhesion intensity between the low-dielectric film 4, the passivation film 7, and the wiring 5 is weak, and therefore there is a possibility that a portion of the removal surface chips off.

On the other hand, in the necessary semiconductor device formation area 22a section, the second grooves 26 has been formed by only the four layers of low-dielectric film 4 being removed by a laser beam irradiation, after the formation of the first grooves 25 by photolithography in the passivation film 7 on the dicing streets 23 formed along the four sides. Accordingly, the adhesion intensity between removal surfaces of the four layers of the low-dielectric film 4 is higher than the adhesion intensity between different types of materials. Therefore, comparatively, a portion of the removal surface does not easily chip off.

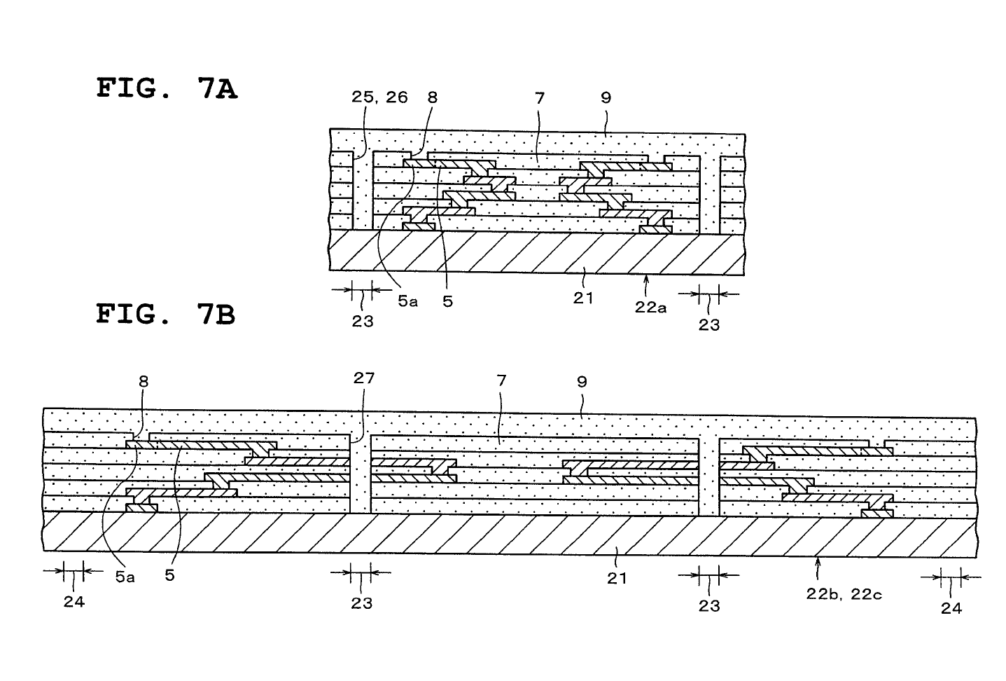

Next, as shown in FIG. 7A and FIG. 7B, in the necessary semiconductor device formation area 22a section and the unnecessary semiconductor device formation area 22b and 22c sections, the protective film 9 made of an organic material such as polyimide resin is formed by screen printing, spin coating, and the like on the upper surface of the passivation film 7 including the upper surface of the connection pad portion 5a of the wiring 5 of the uppermost layer exposed via the opening 8 on the passivation film 7, the upper surface of the semiconductor wafer 21 exposed via the first groove 25 and the second groove 26, and the upper surface of the semiconductor wafer 21 exposed via the third groove 27.

Therefore, in this state, in the necessary semiconductor device formation area 22a section, the removal surface by a laser beam irradiation on the low-dielectric film 4 is covered by the protective film 9 as shown in FIG. 7A. Accordingly, any portion of the removal surface is infallibly prevented from chipping off at the earliest stage possible. In addition, as shown in FIG. 7B, in the unnecessary semiconductor device formation area 22b and 22c sections, the removal surfaces by a laser beam irradiation on the passivation film 7, the low-dielectric film 4, and the wiring 5 are covered by the protective film 9. Therefore, any portion of the removal surface is infallibly prevented from chipping off at the earliest stage possible.

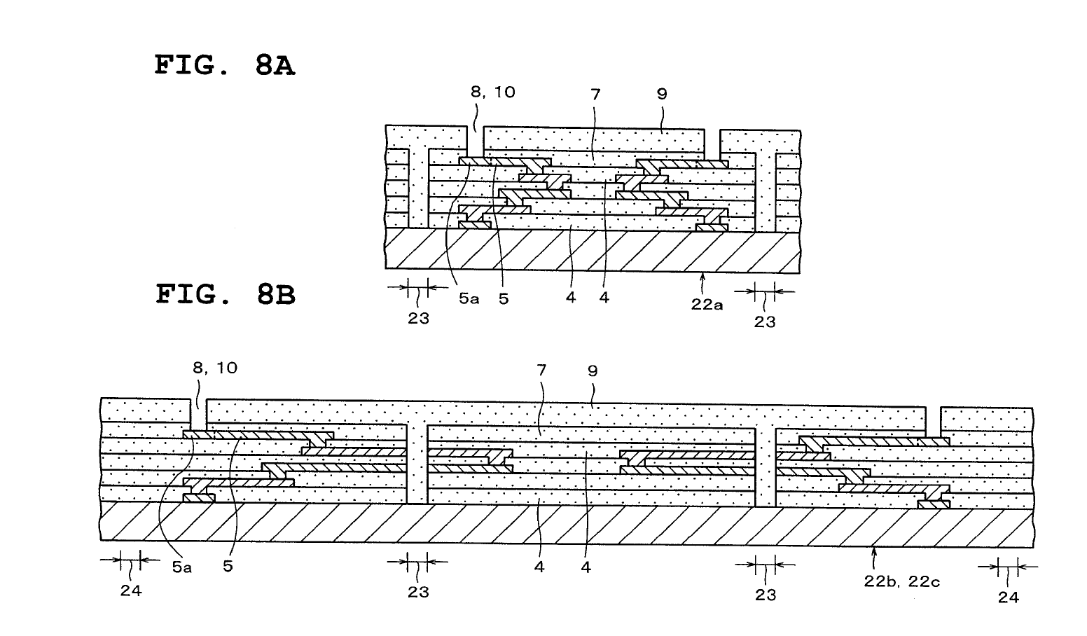

Next, as shown in FIG. 8A and FIG. 8B, a photoresist (not shown) is adhered on the protective film 9. Then, in the necessary semiconductor device formation area 22a section and the unnecessary semiconductor device formation area 22b and 22c sections, the openings 10 and 8 are formed by photolithography in portions of the protective film 9 and the passivation film 7 corresponding to the connection pad portion 5a of the wiring 5 of the uppermost layer.

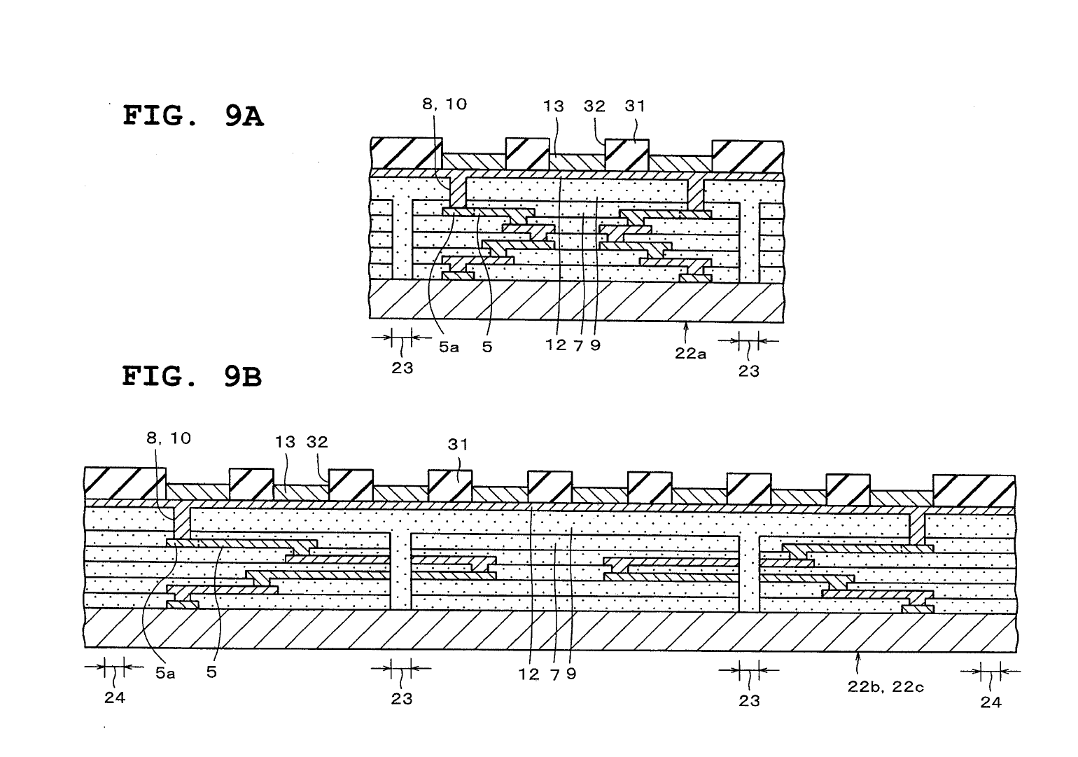

Next, as shown in FIG. 9A and FIG. 9B, the base metallic layer 12 is formed over the overall upper surface of the protective film 9 including the upper surface of the connection pad portion 5a of the wiring 5 of the uppermost layer exposed via the openings 8 and 10 in the passivation film 7 and the protective film 9. In this instance, the base metallic layer 12 may be only a copper layer formed by electroless plating, or may be only a copper layer formed by sputtering. Alternatively, the base metallic layer 12 may be a copper layer formed by sputtering on a thin-film layer of titanium or the like formed by sputtering.

Next, a plating resist film 31 is formed by patterning on the upper surface of the base metallic layer 12. In this instance, in the necessary semiconductor device formation area 22a section and the unnecessary semiconductor device formation area 22b and 22c sections, an opening 32 is formed in portions of the plating resist film 31 corresponding to all upper metallic layer 13 formation areas. Next, electrolytic plating using copper is performed on the base metallic layer 12 serving as a plating current path, thereby forming the upper metallic layer 13 on the upper surface of the base metallic layer 12 within the openings 32 in the plating resist film 31. Next, the plating resist film 31 is peeled off.

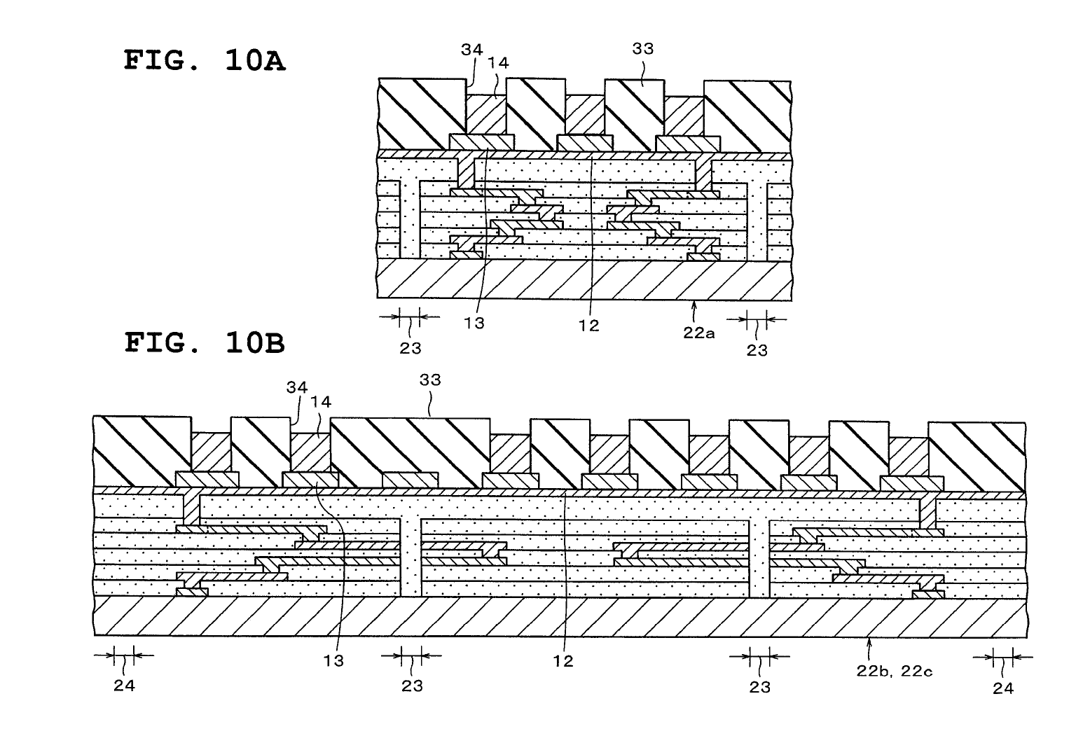

Next, as shown in FIG. 10A and FIG. 10B, a photoresist is adhered to the upper surface of the base metallic layer 12 including the upper metallic layer 13, and a plating resist film 33 is formed by patterning by photolithography. In this instance, in the necessary semiconductor device formation area 22a section, an opening 34 having a circular planar shape is formed in portions of the plating resist film 33 corresponding to all connection pad portions (columnar electrode 14 formation areas) having a circular planar shape on the upper metallic layer 13.

On the other hand, in the unnecessary semiconductor device formation area 22b and 22c sections, to prevent the columnar electrodes 14 from being formed on the upper surface of the connection pad portions of the upper metallic layer 13 in areas corresponding to the dicing streets 23 (and both sides of the dicing streets 23, if required), the openings 34 having a circular planar shape are formed in portions of the plating resist film 33 corresponding to the connection pad portions of the upper metallic layer 13 in areas other than the areas corresponding to dicing streets 23 (and both sides of the dicing streets 23, if required).

Next, electrolytic plating using copper is performed on the base metallic layer 12 serving as a plating current path, thereby forming the columnar electrodes 14 having a circular planar shape on the upper surface of the connection pad portions of the upper metallic layer 13 within the openings 34 in the plating resist film 33. In this state, in the unnecessary semiconductor device formation area 22b and 22c sections, the columnar electrodes 14 are not formed on the upper surface of the connection pad portions of the upper metallic layer 13 in the areas corresponding to the dicing streets 23 (and both sides of the dicing streets 23, if required).

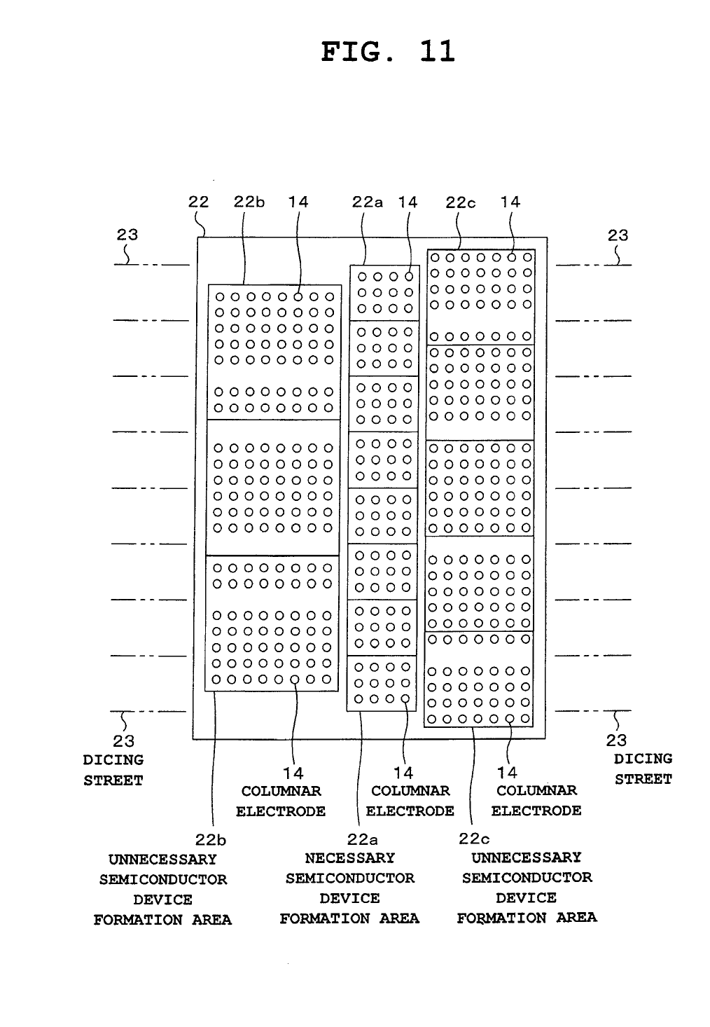

Here, a top view of this state is shown in FIG. 11. As shown in FIG. 11, in the necessary semiconductor device formation area 22a, the columnar electrodes 14 are formed as intended. In the unnecessary semiconductor device formation areas 22b and 22c, the columnar electrodes 14 are formed as intended only in areas excluding areas corresponding to the dicing streets 23 formed along the upper side and the lower side of the necessary semiconductor device formation area 22a and both sides of the dicing streets 23. In the areas corresponding to the dicing streets 23 and both sides of the dicing streets 23, the columnar electrodes 14 are not formed.

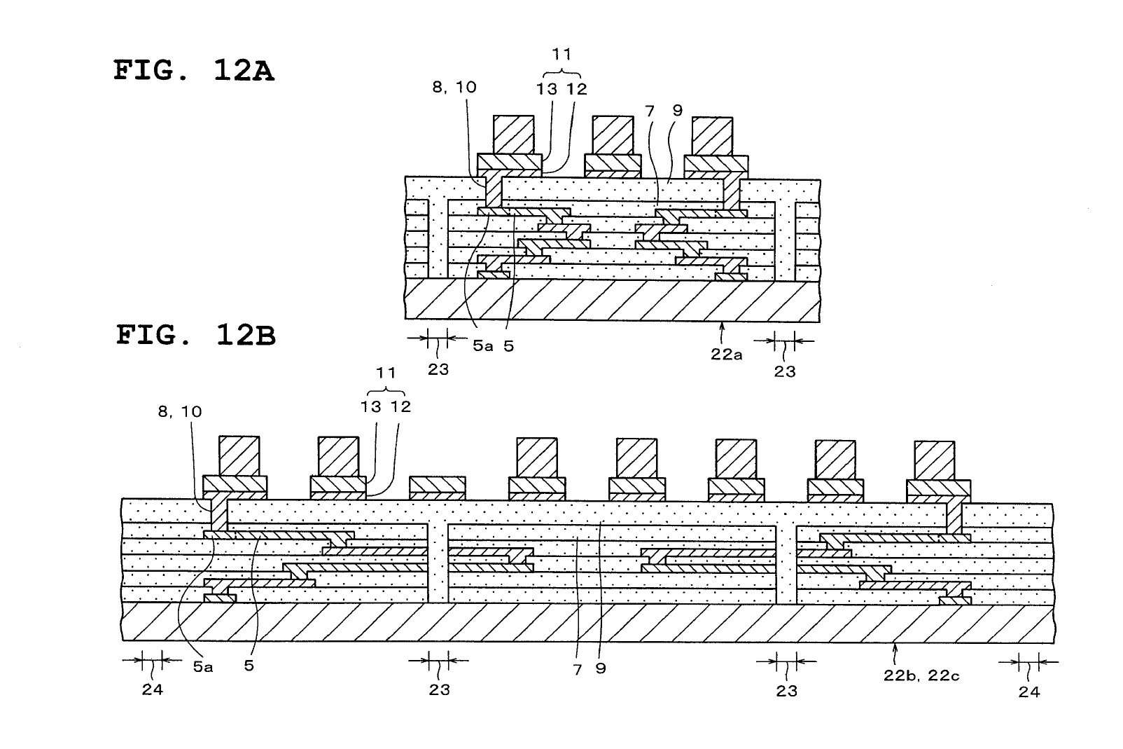

Returning to FIG. 10A and FIG. 10B, next the plating resist film 33 is peeled off. Then, unnecessary portions of the base metallic layer 12 are etched and removed using the upper metallic layer 13 as a mask. As a result, as shown in FIG. 12A and FIG. 12B, the base metallic layer 12 remains only under the upper metallic layer 13. In this state, the upper layer wiring 11 of a double-layered structure consisting of the upper metallic layer 13 and the base metallic layer 12 thereunder has been formed. An end section of the upper layer wiring 11 is connected to the connection pad portion 5a of the wiring 5 of the uppermost layer via the openings 8 and 10 in the passivation film 7 and the protective film 9.

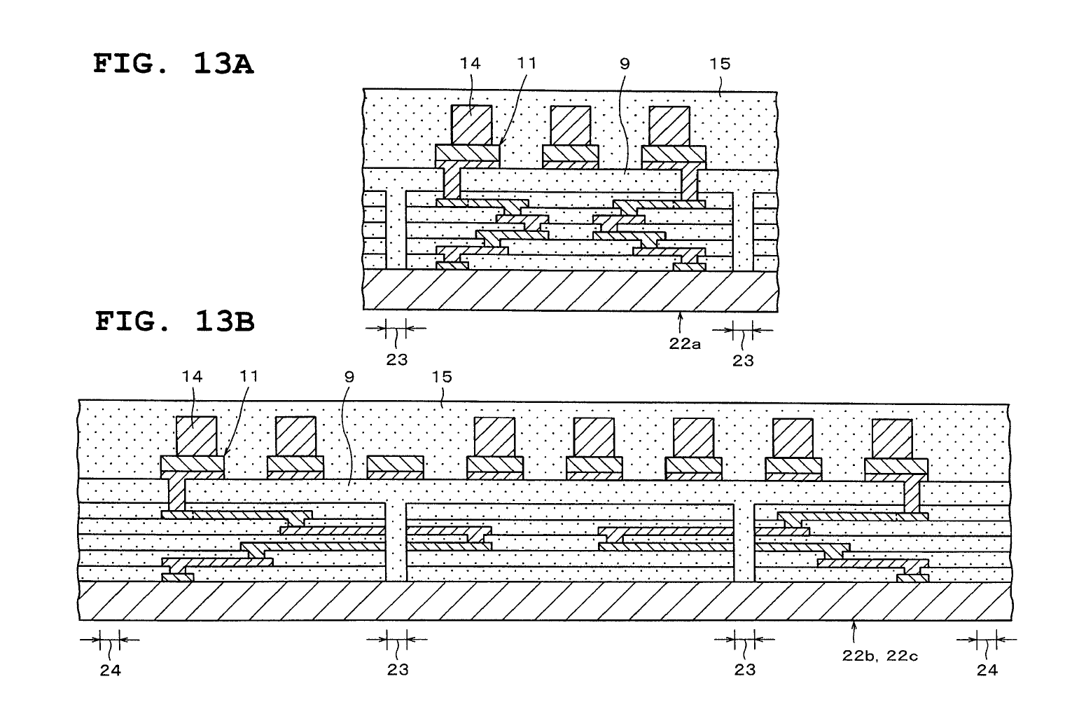

Next, as shown in FIG. 13A and FIG. 13B, the sealing film 15 made of epoxy resin and the like is formed by screen printing, spin coating, and the like on the upper surface of the protective film 9 including the upper wiring 11 and the columnar electrodes 14, such that the thickness of the sealing film 15 is thicker than the height of the columnar electrode 14. Therefore, in this state, the upper surface of the columnar electrode 14 is covered by the sealing film 15.

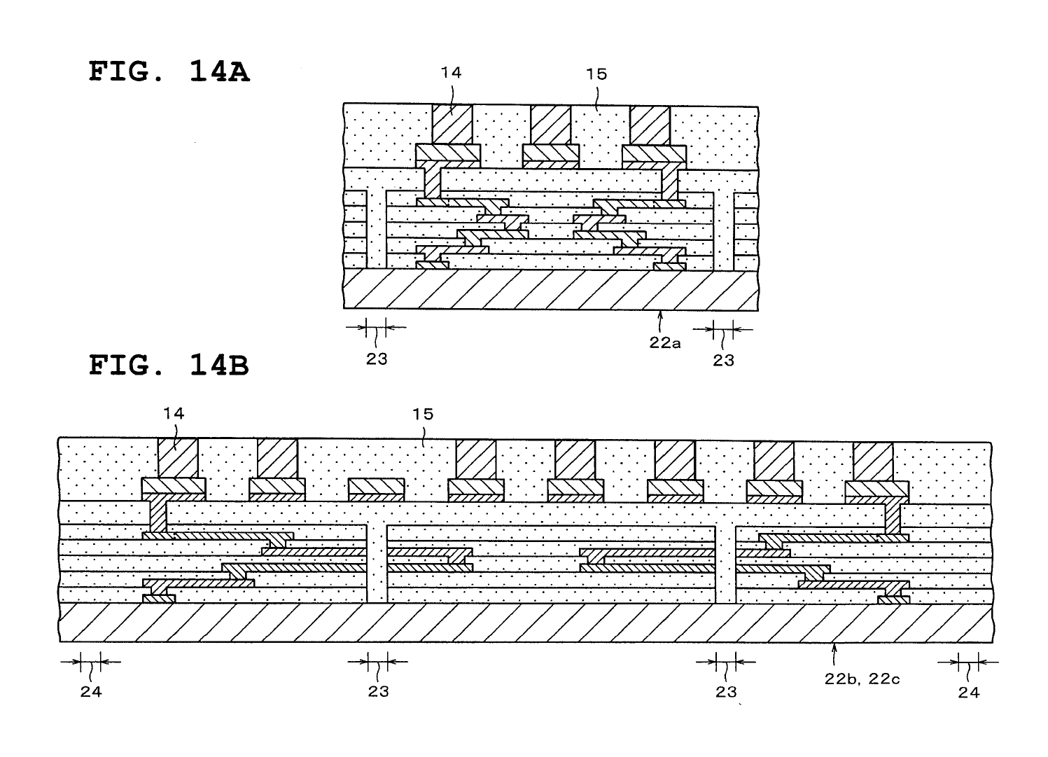

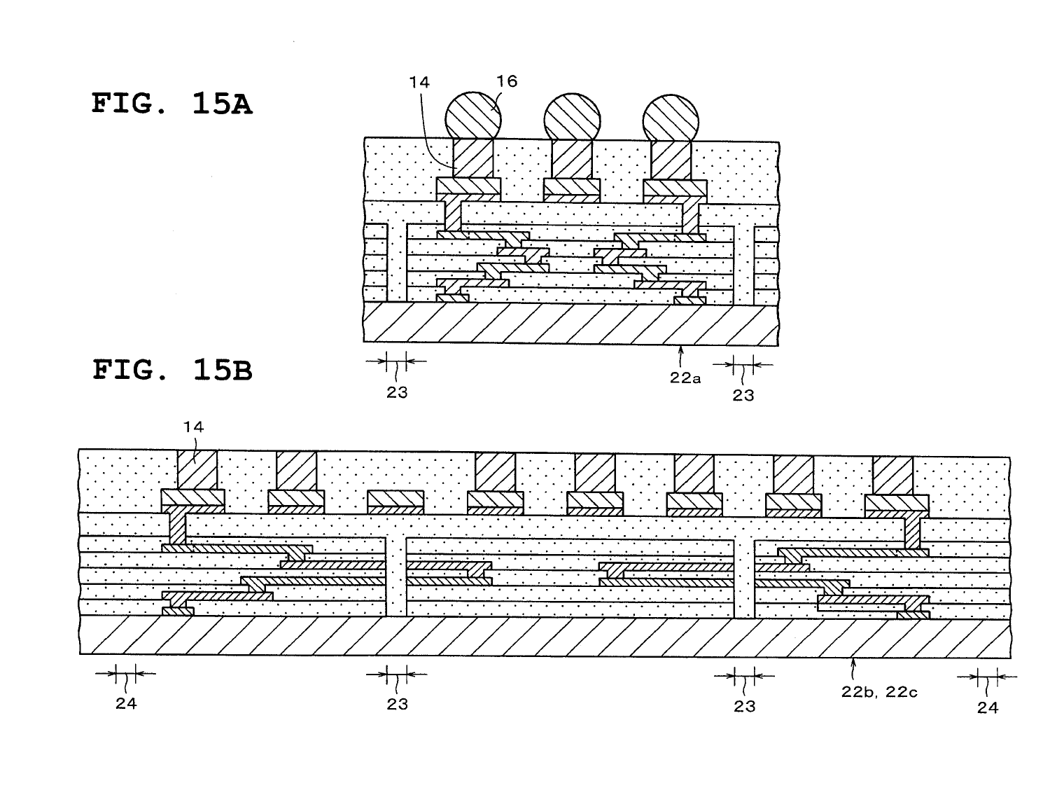

Next, as shown in FIG. 14A and FIG. 14B, the upper surface of the columnar electrode 14 is exposed by the upper surface side of the sealing film 15 being ground accordingly, and the upper surface of the sealing film 15 including the exposed upper surface of the columnar electrode 14 is planarized. Next, as shown in FIG. 15A and FIG. 15B, in the necessary semiconductor device formation area 22a, the solder ball 16 is formed on the top surface of the columnar electrode 14. However, in the unnecessary semiconductor device formation areas 22b and 22c, the solder ball 16 is not formed on the upper surface of the columnar electrode 14. This is because, by minimizing the amount of solder balls 16 used, the cost thereof can be reduced.

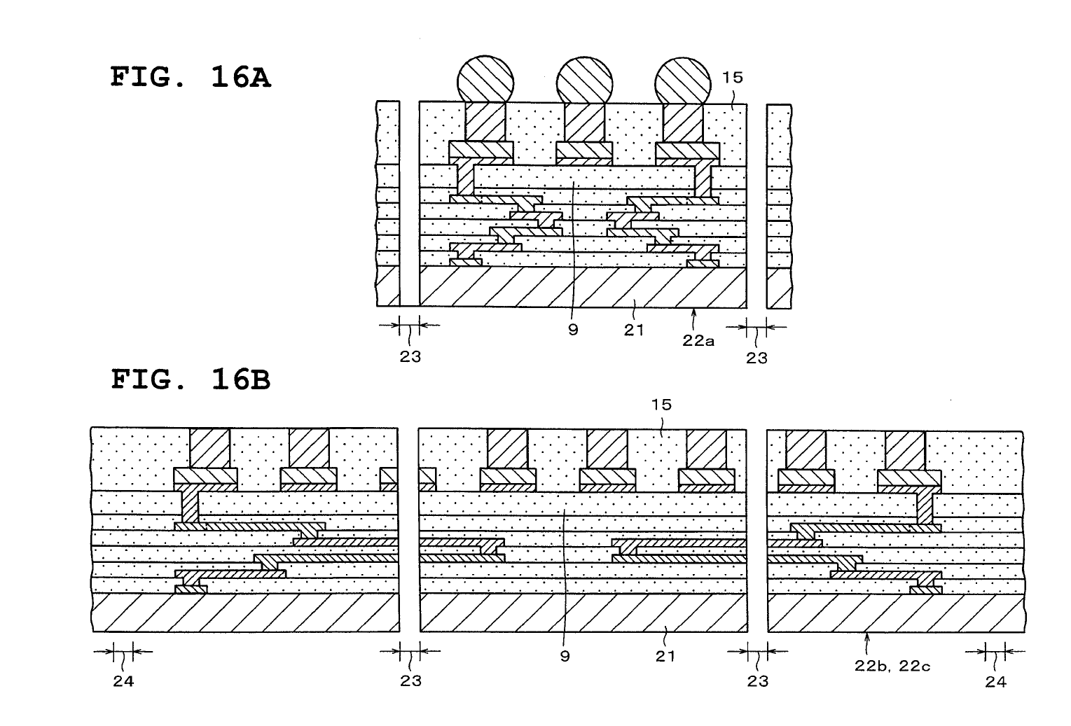

Next, as shown in FIG. 16A and FIG. 16B, the sealing film 15, the protective film 9, and the semiconductor wafer 21 are cut along the dicing streets 23. As a result, the semiconductor device shown in FIG. 1A and FIG. 1B is obtained from the necessary semiconductor device formation area 22a section, and unnecessary semiconductor devices are obtained from the unnecessary semiconductor device formation area 22b and 22c sections.

Here, an explanation regarding the cutting of the sealing film 15, the protective film 9, and the semiconductor wafer 21 along the dicing streets 23 will be given with reference to FIG. 11. In the unnecessary semiconductor device formation areas 22b and 22c, because the columnar electrodes 14 are not formed in the areas corresponding to the dicing streets 23 formed along the upper side and the lower side of the necessary semiconductor device formation area 22a and both sides of the dicing streets 23, the columnar electrodes 14 are not cut by a dicing blade (not shown).

Accordingly, in the above-described manufacturing method, in cutting along the dicing streets 23 by a dicing blade, the columnar electrodes 14 are not cut in the unnecessary semiconductor device formation areas 22b and 22c. Therefore, the dicing blade does not easily become clogged with copper, and the decrease of the life of the dicing blade caused by being clogged with copper is suppressed.

Not forming a single columnar electrode 14 in the overall unnecessary semiconductor device formation areas 22b and 22c is also a way of suppressing the clogging of the dicing blade with copper. However, in this case, because not a single columnar electrode 14 is formed in the overall unnecessary semiconductor device formation areas 22b and 22c, when electrolytic plating is performed to form the columnar electrodes 14 in only the necessary semiconductor device formation area 22a, the plating current is concentrated in the necessary semiconductor device formation area 22a and increases. This is not preferable because uniformity in the height and shape of the columnar electrodes 14 is compromised.

According to the present invention, as show in FIG. 11, in the unnecessary semiconductor device formation areas 22b and 22c, the columnar electrodes 14 are formed as intended only in areas excluding the areas corresponding to the dicing streets 23 formed along the upper side and the lower side of the necessary semiconductor device formation area 22a and both sides of the dicing streets 23, and the columnar electrodes 14 are not formed in the areas corresponding to the dicing streets 23 and both sides of the dicing streets 23. Therefore, uniformity of plating is improved.

Note that, the above range where the columnar electrodes 14 are not formed in the unnecessary semiconductor device formation areas 22b and 22c is not limited to areas directly above the dicing streets 23 formed along the periphery of the necessary semiconductor device formation area 22a. The columnar electrodes 14 may be not formed within a predetermined range from the area directly above the dicing street 23 formed along the periphery of the necessary semiconductor device formation area 22a under the premise that uniformity in the height, shape, and the like of the columnar electrodes 14 formed by electrolytic plating is maintained. In other words, in the unnecessary semiconductor device formation areas 22b and 22c, the columnar electrodes 14 are only required to be formed in areas excluding the non-formation areas including the areas directly above the dicing streets 23 formed along the periphery of the necessary semiconductor device formation area 22a.

### Second Embodiment

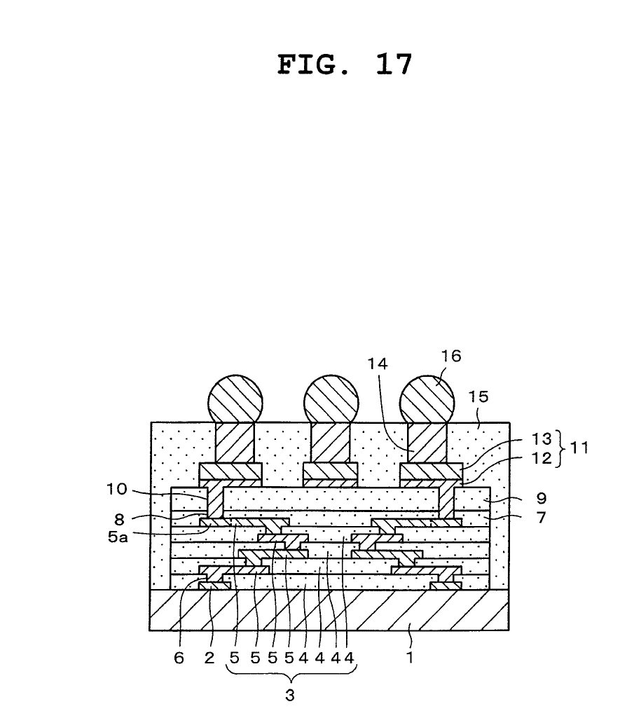

FIG. 17 is a cross-sectional view of an example of a semiconductor device manufactured by a manufacturing method according to the second embodiment of the present invention.

This semiconductor device differs from the semiconductor device in FIG. 1B in that the low-dielectric film wiring laminated structure section 3 is provided on the upper surface of the silicon substrate in an area excluding the outer periphery of the connection pad 2, and that the sealing film 15 is provided on the upper surface periphery of the silicon substrate 1 on the outer side of the low-dielectric film wiring laminated structure section 3.

Next, an example of a manufacturing method of this semiconductor device will be described.

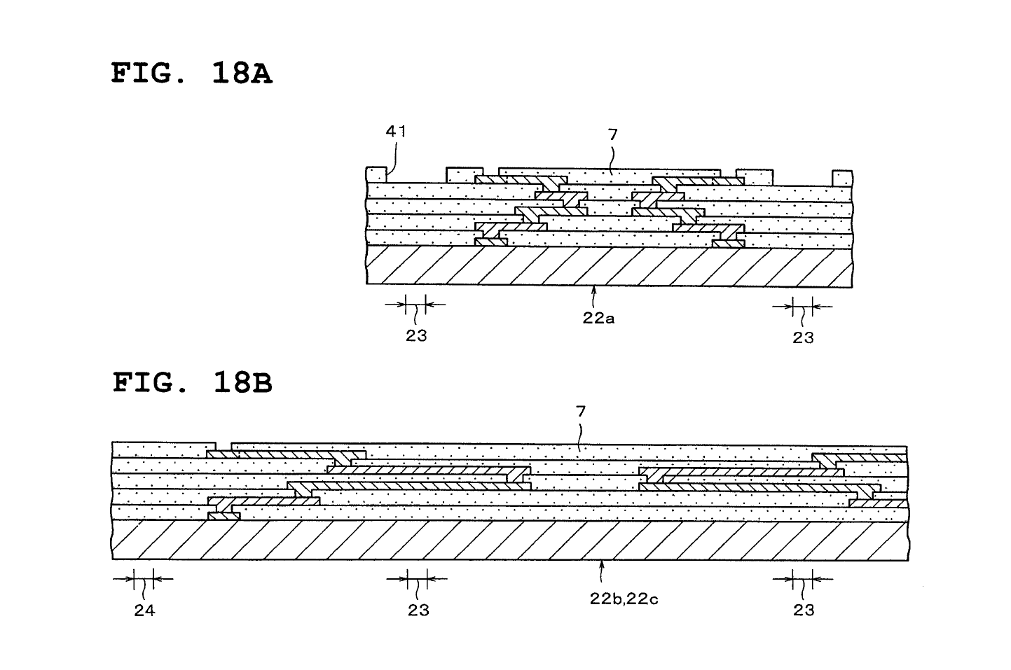

In this instance, after the structure shown in FIG. 4A and FIG. 4B is prepared, a first groove 41 is formed by photolithography in the passivation film 7 in areas on the dicing streets 23 formed along the four sides of the necessary semiconductor device formation area 22a and both sides of the dicing streets 23, as shown in FIG. 18A. In this instance as well, a groove such as this is not formed in the passivation film 7 in the unnecessary semiconductor device formation areas 22b and 22c, as shown in FIG. 18B.

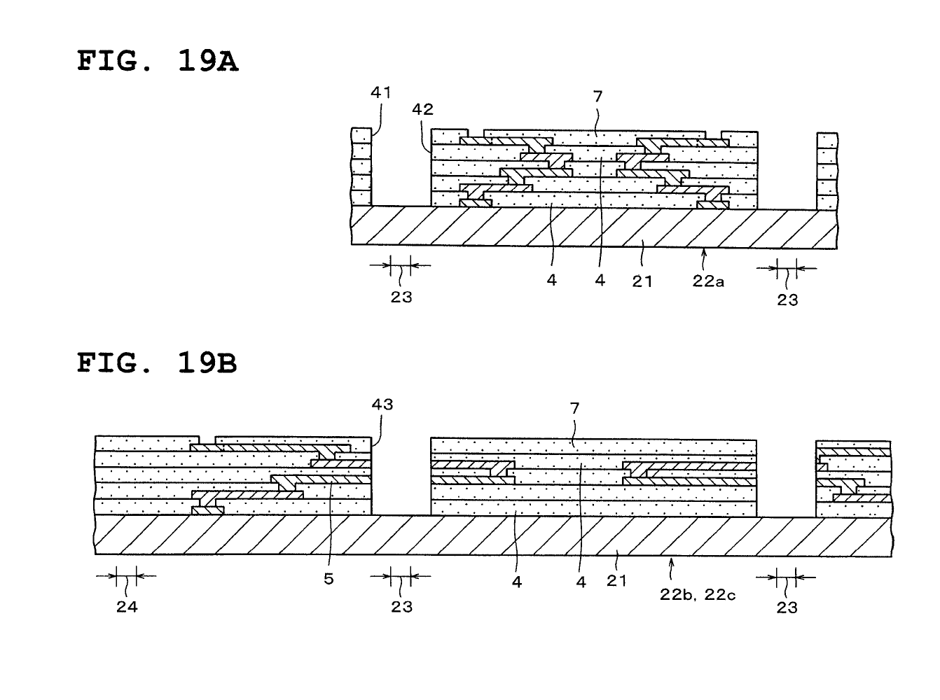

Next, as shown in FIG. 19A, in the necessary semiconductor device formation area 22a section, a second groove 42 is formed in the four layers of the low-dielectric film 4 in an area corresponding to the first groove 41 in the passivation film (in other words, in the areas on the dicing streets 23 and both sides of the dicing streets 23) by laser processing through a laser beam irradiation. In this state, the upper surface of the semiconductor wafer 21 in the areas on the dicing streets 23 and both sides of the dicing streets 23 is exposed via the first groove 41 and the second groove 42.

Next, as shown in FIG. 19B, in the unnecessary semiconductor device formation areas 22b and 22c sections, a third groove 43 is formed in the passivation film 7 and the four layers of low-dielectric film 4 in the areas on the dicing streets 23 and both sides of the dicing streets 23 by laser processing through irradiation of a laser beam. In this instance as well, because a portion of the wiring 5 overlaps with the dicing streets 23 in the unnecessary semiconductor device formation areas 22b and 22c, the wiring 5 in the overlapping portion is removed. In this state, the upper surface of the semiconductor wafer 21 in the areas on the dicing streets 23 and both sides of the dicing streets 23 is exposed via the third groove 43.

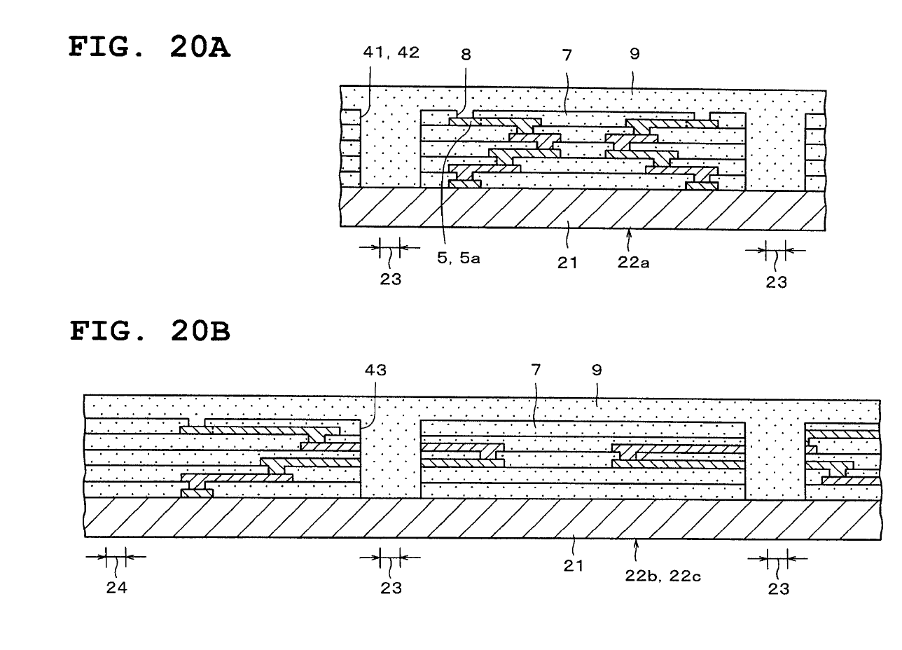

Next, as shown in FIG. 20A and FIG. 20B, the protective film 9 made of an organic material, such as polyimide resin, is formed by screen printing, spin coating, and the like on the upper surface of the passivation film 7 including the upper surface of the connection pad portion 5a of the wiring 5 of the uppermost layer exposed via the opening 8 in the passivation film 7, the upper surface of the semiconductor wafer 21 exposed via the first groove 41 and the second groove 42, and the upper surface of the semiconductor wafer 21 exposed via the third groove 43, in the necessary semiconductor device formation area 22a.

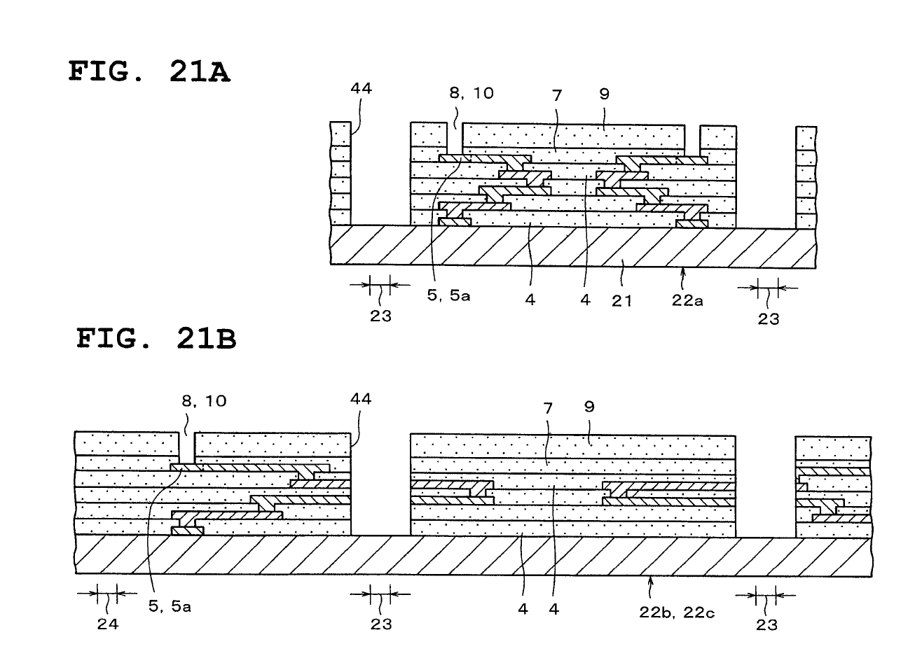

Next, as shown in FIG. 21A and FIG. 21B, in the necessary semiconductor device formation area 22a section and the unnecessary semiconductor device formation area 22b and 22c sections, the openings 10 and 8 are formed by photolithography in portions of the protective film 9 and the passivation film 7 corresponding to the connection pad portion 5a of the wiring 5 of the uppermost layer. In addition, a groove 44 is formed by photolithography in the protective film 9, the passivation film 7, and the four layers of low-dielectric film 4 in the areas on the dicing streets 23 and both sides of the dicing streets 23. Hereafter, when procedures similar to those according to the above-described first embodiment are performed, the semiconductor device shown in FIG. 17 is obtained from the necessary semiconductor device formation area 22a section, and unnecessary semiconductor devices are obtained from the unnecessary semiconductor device formation area 22b and 22c sections.

Once completed, the semiconductor device shown in FIG. 17 obtained from the necessary semiconductor device formation area 22a section is provided with the low-dielectric film wiring laminated structure section 3 in an area excluding the upper surface periphery of the silicon substrate 1. In addition, the side surfaces of the low-dielectric film wiring laminated structure section 3, the passivation film 7, and the protective film 9 are covered by the sealing film 15. Therefore, in this structure, the low-dielectric film wiring laminated structure section 3 is not easily peeled off from the silicon substrate 1.

### Third Embodiment

Next, the third embodiment of the present invention will be described.

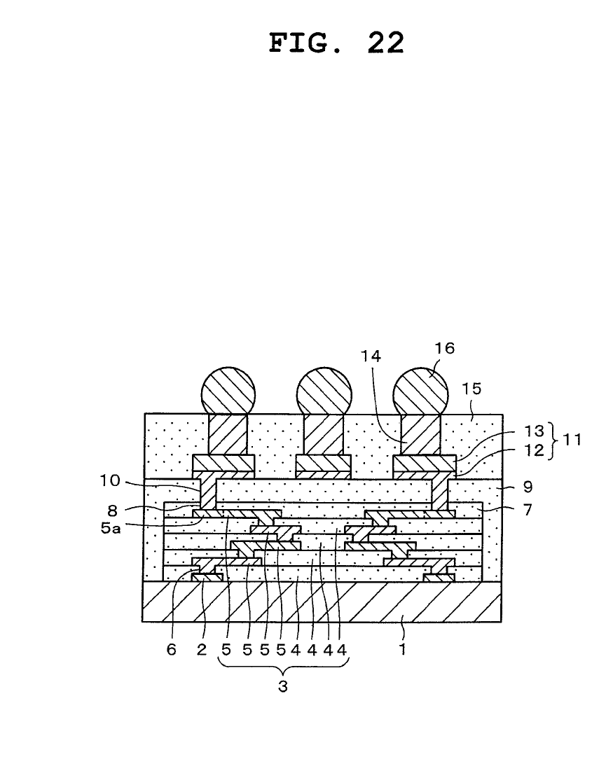

FIG. 22 is a cross-sectional view of an example of a semiconductor device manufactured by a manufacturing method according to a third embodiment of the present invention.

This semiconductor device differs from the semiconductor device shown in FIG. 1B in that the low-dielectric film wiring laminated structure section 3 is provided on the upper surface of the silicon substrate in an area excluding the outer periphery of the connection pad 2, and that the protective film 9 is provided on the upper surface periphery of the silicon substrate 1 on the outer side of the low-dielectric film wiring laminated structure section 3.

Next, an example of a manufacturing method of the semiconductor device will be described.

In this instance, only the openings 8 and 10 are formed, and the groove 44 is not formed in the procedure shown in FIG. 21. Hereafter, after procedures similar to those according to the above-described first embodiment, the semiconductor device shown in FIG. 22 is obtained from the necessary semiconductor device formation area 22a section, and unnecessary semiconductor devices are obtained from the unnecessary semiconductor device formation area 22b and 22c sections.

Once completed, the semiconductor device shown in FIG. 22 obtained from the necessary semiconductor device formation area 22a section is provided with the low-dielectric film wiring laminated structure section 3 in an area excluding the upper surface periphery of the silicon substrate 1. In addition, the side surfaces of the low-dielectric film wiring laminated structure section 3 and the passivation film 7 are covered by the protective film 9. Therefore, in this structure, the low-dielectric film wiring laminated structure section 3 is not easily peeled off from the silicon substrate 1.

### Fourth Embodiment

Next, the fourth embodiment of the present invention will be described.

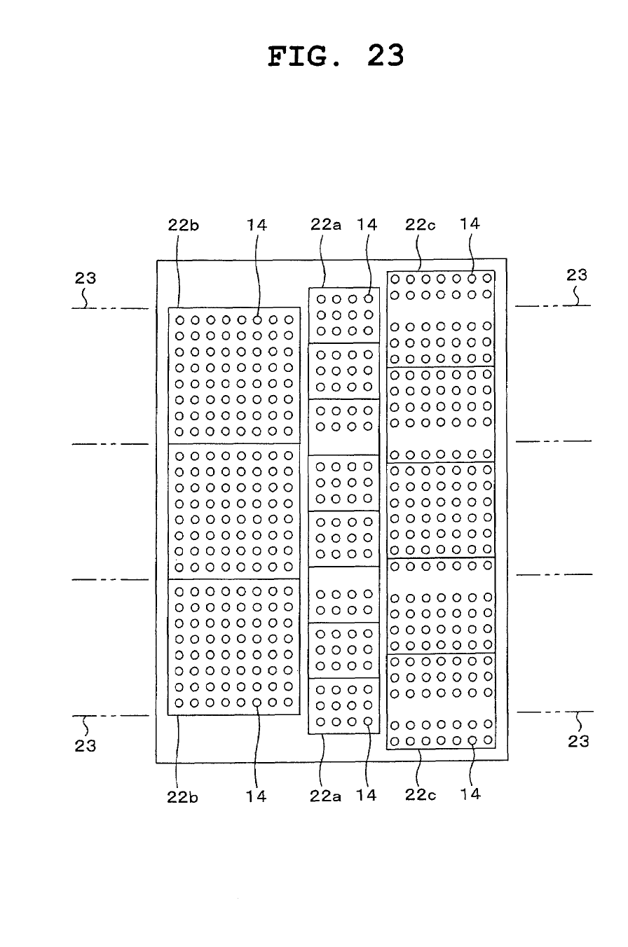

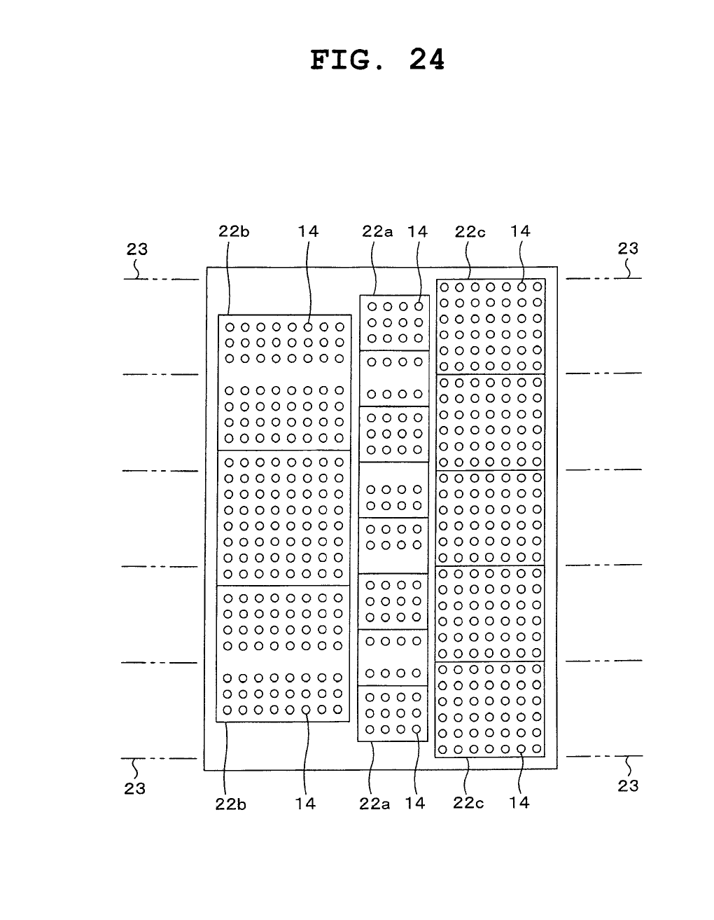

In FIG. 3, when supposing that reference numeral 22b indicates a necessary semiconductor device formation area, and reference numerals 22a and 22c indicate unnecessary semiconductor device formation areas, as shown in FIG. 23 that is a planar view of a procedure similar to that in FIG. 11, areas along the upper side and the lower side of the necessary semiconductor device formation area indicated by reference numeral 22b are the dicing streets 23.

In this case, in the necessary semiconductor device formation area indicated by reference numeral 22b, the columnar electrodes 14 have been formed as intended. Also, in the unnecessary semiconductor device formation areas indicated by the reference numerals 22a and 22c, the columnar electrodes 14 have been formed as intended only in areas excluding areas corresponding to the dicing streets 23 formed along the upper side and the lower side of the necessary semiconductor device formation area indicated by reference numeral 22b and both sides of the dicing streets 23. That is, the columnar electrodes 14 have not been formed in the areas corresponding to the dicing streets 23 and both sides of the dicing streets 23.

### Fifth Embodiment

Next, the fifth embodiment of the present invention will be described.

In FIG. 3, when supposing that reference numeral 22c indicates a necessary semiconductor device formation area, and reference numerals 22a and 22b indicate unnecessary semiconductor device formation areas, as shown in FIG. 23 that is a planar view of a procedure similar to that in FIG. 11, areas along the upper side and the lower side of the necessary semiconductor device formation area indicated by reference numeral 22c are the dicing streets 23.

In this case, in the necessary semiconductor device formation area indicated by reference numeral 22c, the columnar electrodes 14 have been formed as intended. Also, in the unnecessary semiconductor device formation areas indicated by reference numerals 22a and 22b, the columnar electrodes 14 have been formed as intended only in areas excluding areas corresponding to the dicing streets 23 formed along the upper side and the lower side of the necessary semiconductor device formation area indicated by reference numeral 22c and both sides of the dicing streets 23. That is, the columnar electrodes 14 have not been formed in the areas corresponding to the dicing streets 23 and both sides of the dicing streets 23.

### Another Embodiment 1

Other embodiments according to the present invention will be described.

First, another embodiment 1 will be described.

For example, in the above-described first embodiment, in a case where the openings 10 and 8 are formed in the protective film 9 and the passivation film 7, the opening 32 is formed in the plating resist film 31 for forming the upper metal layer (FIG. 9), and the opening 34 is formed in the plating resist film 33 for forming the columnar electrodes (FIG. 10) by photolithography, a dedicated exposure mask is used for each of the openings 10, 8, 32, and 34.

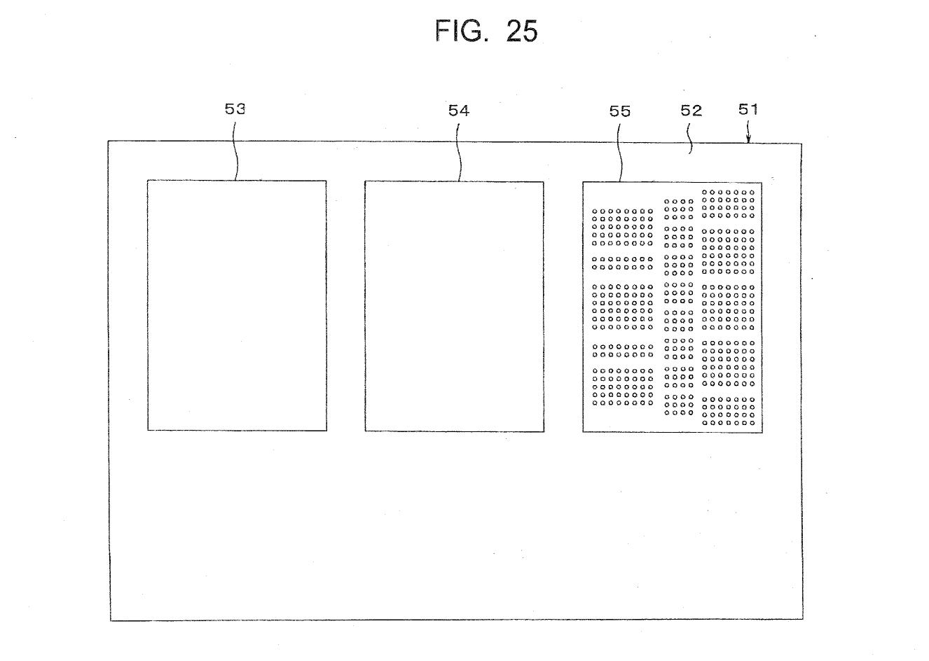

In this case, as shown in FIG. 25, a single glass plate 52, on the upper surface of which a first exposure mask section (generally referred to as a field; the same applies hereafter) 53 for forming the openings 10 and 8 in the protective film 9 and the passivation film 7 (illustration of a blocking section for an area corresponding to the opening 10 or 8 is omitted), a second exposure mask section 54 for forming the opening 32 in the plating resist film 31 for forming an upper metal layer (illustration of a blocking section for an area corresponding to the opening 32 is omitted), and a third exposure mask section 55 for forming the opening 34 in the plating resist film 34 for forming columnar electrodes are formed, may be used as an exposure mask (generally referred to as a reticle) 51, and in this case, only a single exposure mask is required. However, in the exposure mask 51, the third exposure mask section 55 for forming columnar electrodes has a mask pattern in which the semiconductor device formation area 22a is the necessary semiconductor device formation area, and the semiconductor device formation areas 22b and 22c are discarded as unnecessary semiconductor device formation areas.

As described above, since a single exposure mask is required when the semiconductor device formation area 22a is a necessary semiconductor device formation area, an exposure mask in which the semiconductor device formation area 22b is a necessary semiconductor device formation area, and an exposure mask in which the semiconductor device formation area 22c is a necessary semiconductor device formation area are similarly required to be formed. In a method such as that shown in FIG. 25 in which respective exposure masks are used to set each semiconductor device formation area to a necessary semiconductor device formation area, a total of three exposure masks are required. Therefore, a method of fabricating an exposure mask allowing the number of exposure masks to be reduced in such a case will be described next.

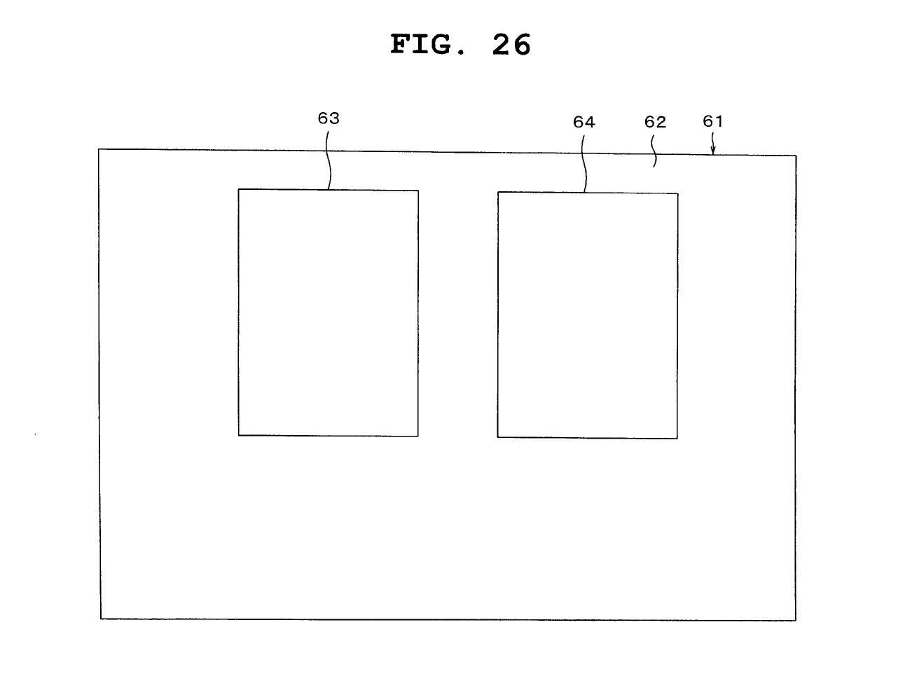

Firstly, as shown in FIG. 26, a first exposure mask 61 is fabricated which has, on the left side and the right side of a glass substrate 62, an exposure mask section 63 for forming the openings 10 and 8 in the protective film 9 and the passivation film 7 (illustration of a blocking section for an area corresponding to the opening 10 or 8 is omitted) and an exposure mask section 64 for forming the opening 32 in the plating resist film 31 for forming an upper metal layer (illustration of a blocking section for an area corresponding to the opening 32 is omitted).

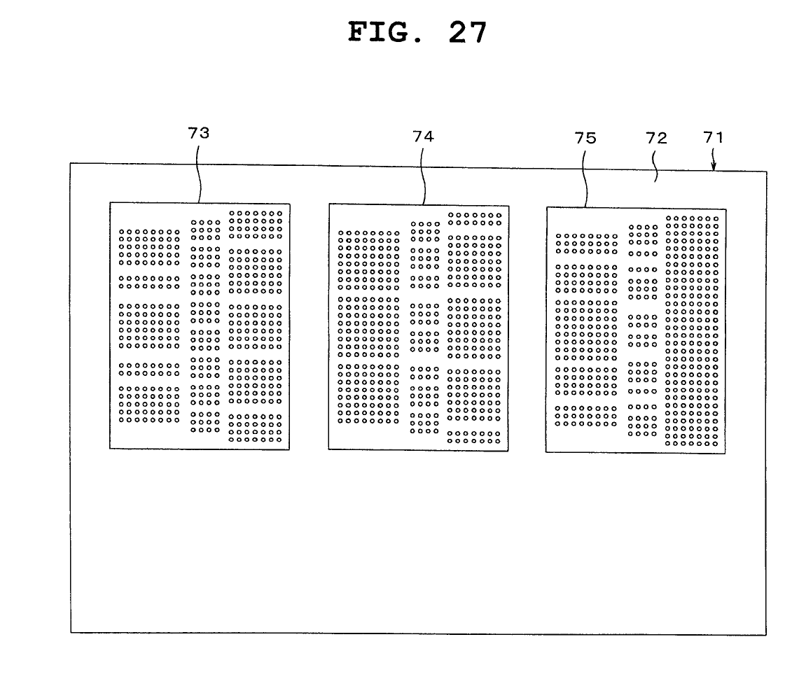

In addition, as shown in FIG. 27, a second exposure mask 71 is fabricated which has, on a glass substrate 72, three exposure mask sections 73 to 75 in which one of the semiconductor device formation areas 22a, 22b, and 22c is a necessary semiconductor device formation area and the other two are unnecessary semiconductor device formation areas. In FIG. 27, in the exposure mask section 73 on the left side, the semiconductor device formation area 22a is a necessary semiconductor formation area, and the semiconductor device formation areas 22b and 22c are unnecessary semiconductor device formation areas. In the exposure mask section 74 in the center, the semiconductor device formation area 22b is a necessary semiconductor formation area, and the semiconductor device formation areas 22a and 22c are unnecessary semiconductor formation areas. In the exposure mask 75 on the right side, the semiconductor device formation area 22c is a necessary semiconductor formation area, and the semiconductor device formation areas 22a and 22b are unnecessary semiconductor formation areas.

That is, the exposure mask section 63 used to form the openings 10 and 8 in the protective film 9 and the passivation film 7 and the exposure mask section 64 used to form the opening 32 in the plating resist film 31 for forming an upper metal layer are formed in the single first exposure mask 61. In addition, for the exposure mask section used to form the opening 34 in the plating resist film 33 for forming columnar electrodes, the three exposure mask sections 73 to 75 in each of which one of the semiconductor device formation areas is a necessary semiconductor device formation area are formed on a single second exposure mask 71. Thus, only two exposure masks are required.

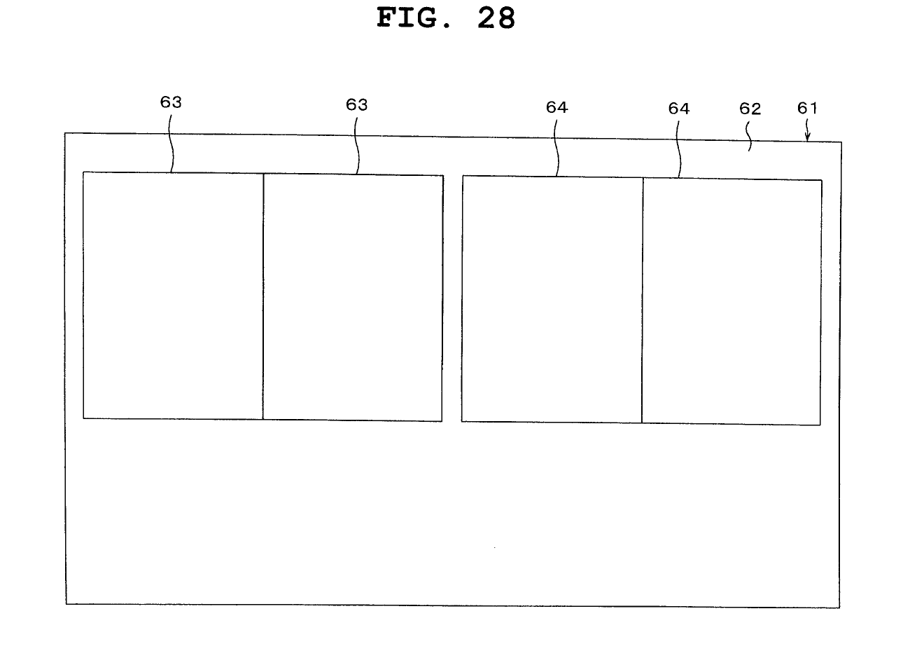

When there is surplus space in the horizontal direction of the exposure mask, instead of the exposure mask 61 shown in FIG. 26, as shown in FIG. 28, an exposure mask may be used in which two exposure mask sections 63 used to form the openings 10 and 8 in the protective film 9 and the passivation film 7 are formed and aligned in the horizontal direction on the left side of the upper surface of the single glass substrate 62, and two exposure mask sections 64 used to form the opening 32 in the plating resist film 31 for forming an upper metal layer are formed and aligned in the horizontal direction on the right side of the upper surface of the single glass substrate 62.

When an exposure mask 61 such as this is used, for example, two areas 22 such as shown in FIG. 11 that are adjacent in the horizontal direction are exposed simultaneously by the two exposure masks 63 or the two exposure masks 64. Therefore, frequency of exposure performed on a single semiconductor wafer 21 is reduced, and exposure time is shortened.

### Another Embodiment 2

Next, another embodiment 2 will be described.

According to the above-described first embodiment, as shown in FIG. 9A and FIG. 9B, in the necessary semiconductor device formation area 22a section and the first unnecessary semiconductor device area 22b section, the opening 32 is formed in portions of the plating resist film 31 corresponding to all upper metallic layer 13 formation areas.

On the other hand, to prevent at least the connection pad portion of the upper metallic layer 13 from being formed in areas corresponding to the dicing streets 23 (and both sides of the dicing streets 23, if required), in the first unnecessary semiconductor device formation area 22b section, the opening 32 may be formed in portions of the plating resist film 31 corresponding to the upper metallic layer 13 formation areas in areas excluding the areas corresponding to the dicing streets 23 (and both sides of the dicing streets 23, if required).

In this instance, in the first unnecessary semiconductor device formation area 22b section, at least the connection pad portion of the upper metallic layer 13 is not formed in the areas corresponding to the dicing streets 23 (and both sides of the dicing streets 23, if required). Therefore, when explained with reference to FIG. 11, in cutting along the dicing streets 23 by a dicing blade, not only the columnar electrodes 14 but also the connection pad portions of the upper metal wiring 11 serving as base for the columnar electrodes 14 are not cut in the first unnecessary semiconductor device formation area 22b and the second unnecessary semiconductor device formation area 22c. Accordingly, the dicing blade is further prevented from being clogged with copper. Thus, the decrease of the life of a dicing blade caused by being clogged with copper is further suppressed.

Lastly, in the embodiments as described above, a case where circuit wiring connecting each element in a integrated circuit has a low-dielectric film is described. However, the present invention is not limited to the above-described embodiments. In other words, the present invention may be applied to a structure in which each element in a integrated circuit is connected by an insulating film having an ordinary dielectric constant and wiring. In this case, the insulating film may only be cut when the silicon substrate is cut to obtain individual semiconductor devices.

While the present invention has been described with reference to the preferred embodiments, it is intended that the invention be not limited by any of the details of the description therein but includes all the embodiments which fall within the scope of the appended claims.

What is claimed is:

1. A manufacturing method of a semiconductor device, comprising the steps of:
preparing a semiconductor wafer, which has a plurality of semiconductor device formation areas, and on which a low-dielectric film wiring laminated structure section where a low-dielectric film and wiring are laminated is formed;
irradiating a laser beam to form a groove by removing an area of the low-dielectric film wiring laminated structure section corresponding to a dicing street of the semiconductor device formation area; and
forming a protective film on the low-dielectric film wiring laminated structure section and within the groove.

2. The manufacturing method of a semiconductor device according to claim 1, comprising the steps of:
wherein, in the step of preparing the semiconductor wafer, which has a plurality of semiconductor device formation areas of different sizes including a necessary semiconductor device formation area and an unnecessary semiconductor device formation area,
forming upper layer wiring on the protective film so as to be connected to the wiring;
forming a columnar electrode on a connection pad portion of the upper layer wiring in the necessary semiconductor device formation area and forming a columnar electrode on a connection pad portion of the upper layer wiring in an area excluding a non-formation area that includes an area corresponding to the dicing street in the unnecessary semiconductor device formation area; and
dicing to obtain a semiconductor device having the necessary semiconductor device formation area by cutting the protective film and the semiconductor wafer along the dicing street.

3. The manufacturing method of a semiconductor device according to claim 2, wherein, in the step of preparing the semiconductor wafer, the unnecessary semiconductor device formation area has an area corresponding to the dicing street.

4. The manufacturing method of a semiconductor device according to claim 3, wherein the low-dielectric film and the wiring in the low-dielectric film wiring laminated structure section are formed in a portion of the area corresponding to the dicing street in the unnecessary semiconductor device formation area.

5. The manufacturing method of a semiconductor device according to claim 4, wherein the low-dielectric film is formed but the wiring is not formed in an area corresponding to the dicing street around the periphery of the necessary semiconductor device formation area.

6. The manufacturing method of a semiconductor device according to claim 1, wherein the step of preparing a semiconductor wafer includes preparing a semiconductor wafer on which a passivation film is formed on the low-dielectric film wiring laminated structure section and forming a first groove by removing the passivation film in the area corresponding to the dicing street by photolithography, and the step of irradiating a laser beam includes forming a second groove by removing the low-dielectric film exposed via the first groove by a laser beam irradiation and forming a third groove by removing the passivation film and the low-dielectric film wiring laminated structure section in other areas corresponding to the dicing street by a laser beam irradiation.

7. The manufacturing method of a semiconductor device according to claim 1, wherein the step of preparing a semiconductor wafer includes preparing a semiconductor wafer on which a passivation film is formed on the low-dielectric film wiring laminated structure section and forming a first groove by removing the passivation film in an area on the dicing street and both sides of the dicing street by photolithography, and the step of irradiating a laser beam includes forming a second groove by removing the low-dielectric film exposed via the first groove by a laser beam irradiation and forming a third groove by removing the passivation film and the low-dielectric film wiring laminated structure section in other areas on the dicing street and both sides of the dicing street by a laser beam irradiation.

8. The manufacturing method of a semiconductor device according to claim 6, comprising the step of:
forming a sealing film around the periphery of the columnar electrode;
wherein the semiconductor device having the necessary semiconductor device formation area is obtained by the sealing film, the protective film, and the semiconductor wafer being cut along the dicing street.

9. The manufacturing method of a semiconductor device according to claim 7, comprising the step of:
forming a sealing film around the periphery of the columnar electrode;
wherein the semiconductor device having the necessary semiconductor device formation area is obtained by the sealing film, the protective film, and the semiconductor wafer being cut along the dicing street.

10. The manufacturing method of a semiconductor device according to claim 7, comprising the steps of:
forming a groove in the protective film in the area corresponding to the dicing street; and
forming a sealing film around the periphery of the columnar electrode and within the groove;
wherein the semiconductor device having the necessary semiconductor device formation area is obtained by the sealing film, the protective film, and the semiconductor wafer being cut along the dicing street.

11. The manufacturing method of a semiconductor device according to claim 1, wherein the step of preparing a semiconductor wafer includes preparing a semiconductor wafer on which a passivation film is formed under the protective film, and the step of forming a protective film and the step of forming upper layer wiring include adhering a photoresist on the protective film and exposing the photoresist using a single sheet of exposure mask having an exposure mask section for forming an opening in the protective film and the passivation film in an area corresponding to a connection pad portion of the wiring and an exposure mask section for forming the upper layer wiring.

12. The manufacturing method of a semiconductor device according to claim 11, wherein the step of forming a columnar electrode includes arranging a photoresist on a connection pad portion of the upper layer wiring and exposing the photoresist using an exposure mask, and wherein the photoresist is exposed using a single sheet of exposure mask including a plurality of exposure mask sections in which one semiconductor device formation area is a necessary semiconductor device formation area and other semiconductor device formation areas are unnecessary semiconductor device formation areas, and the necessary semiconductor device formation area and the unnecessary semiconductor device formation area are semiconductor device formation areas having planar sizes that are different with respect to each other.

13. A semiconductor device manufactured by the manufacturing method of the semiconductor device according to claim 1.
